(19) United States
(12) Patent Application Publication
(10) Pub. No.: US 2002/0127760 A1
(43) Pub. Date: Sep. 12, 2002

(54) Method and apparatus for micro electro-mechanical systems and their manufacture

(76) Inventors: Jer-Liang Yeh, Ithaca, NY (US); Norman C. Tien, Davis, CA (US)

Correspondence Address: SCHWEGMAN, LUNDBERG, WOESSNER & KLUTH, P.A., P.O. BOX 2938, MINNEAPOLIS, MN, 55402, US

(21) Appl. No.: 09/922,590

(22) Filed: Aug. 2, 2001

Related U.S. Application Data
(60) Provisional application No. 60/222,511, filed on Aug. 2, 2000.

(51) Int. Cl. H01L 21/00

(52) U.S. Cl. 438/50; 438/52; 438/53; 438/48

(57) ABSTRACT

The present invention provides a fabrication process that integrates high-aspect-ratio silicon structures with polysilicon surface micromachined structures. In some embodiments the process includes forming an oxide block by etching a plurality of trenches to leave a plurality of vertical-walled silicon structures standing on the substrate, thermally and substantially completely oxidizing the vertical-walled silicon structures, and substantially filling spaces between the oxidized vertical-walled silicon structures with an oxide of silicon to form the oxide block. The process retains not only the high-aspect-ratio silicon structures possible with deep reactive ion etching (DRIE) but also the design flexibility of polysilicon surface micromachining. Using this process, polysilicon platforms have been fabricated, which are actuated by high-aspect-ratio combdrives for many applications such as x-y-z stages and scanning devices. The actuators include an asymmetric combdrive that actuates in torsional/out-of-plane motions, and a high-aspect-ratio combdrive that drives in translational motion.

### CROSS-REFERENCES TO RELATED INVENTIONS

The following commonly assigned U.S. patent applications are relied upon and hereby incorporated by reference in this application:

U.S. Provisional Patent Application No. 60/222,511, entitled “METHOD AND APPARATUS FOR MICRO ELECTRO-MECHANICAL SYSTEMS AND THEIR MANUFACTURE” filed Aug. 2, 2000, bearing attorney docket no. 1153.013prv, and

U.S. Patent Application No. ______, entitled “MICROMACHINE DIRECTIONAL MICROPHONE AND ASSOCIATED METHOD” filed on even date herewith, bearing attorney docket no. 1153.030us1.

### FIELD OF THE INVENTION

This invention relates to the field of micromechanical sensors, and more specifically to a method and apparatus for making micromechanical devices using a sacrificial oxide block.

### Background of the Invention

Microelectromechanical systems (MEMS) refers to a technology in which electrical and mechanical devices are fabricated at substantially microscopic dimensions utilizing techniques well known in the manufacture of integrated circuits. Applications of MEMS technology include pressure, sound and inertial sensing, light deflection with an emphasis on automotive applications thereof. For an introduction to the use of MEMS technology for sensors and actuators, see for example the article by Bryzek et al. in IEEE Spectrum, May 1994, pp. 20-31.

Many of the fabrication processes for MEMS, called micromachining, are borrowed from the integrated circuit industry, where semiconductor devices are fabricated using a sequence of patterning, deposition, and etch steps. Surface micromachining has typically used a deposited layer of polysilicon as the structural micromechanical material. The polysilicon is deposited over a sacrificial layer onto a substrate, typically silicon, and when the sacrificial layer is removed the polysilicon remains free standing. Bulk micromachining techniques, rather than using deposited layers on a silicon substrate, etch directly into the silicon wafer to make mechanical structures of the single crystal silicon itself. Bulk micromachining was first practiced using anisotropic wet chemical etchants such as potassium hydroxide, which preferentially etch faster in certain crystallographic planes of silicon. However, advancements in reactive ion etching (RIE) technology have made practical, and in many ways preferential, the use of dry plasma etching to define micromechanical structures. Reactive ion etching techniques are independent of crystal orientation, and can create devices exceeding the functionality of surface micromachined devices. The use of single-crystal materials, particularly silicon, can be beneficial for mechanical applications because of the lack of defects and grain boundaries, maintaining excellent structural properties even as the size of the device shrinks.

Silicon micromachining has been utilized since the early 1960s. At its early stage, anisotropic single-crystal silicon etching technology was employed in the majority of the research efforts. In the early 1980s, surface micromachining using sacrificial etching gave rise to new types of microsensors and microactuators. More recently, deep reactive ion etching (DRIE) technology has given tremendous impetus to high-aspect-ratio dry-etching of single-crystal silicon. DRIE techniques developed specifically for the MEMS industry have enabled a greater range of functionality for bulk micromachining. Processes, such as those described in U.S. Pat. No. 5,501,893, are now supplied by commercial etch vendors specifically for bulk micromachining. These processes provide silicon etch rates in excess of 2 μm/min with vertical profiles and selectivity to photoresist greater than 50:1 or selectivity to silicon oxide greater than 100:1. This enables bulk micromachined structures to span the range from several microns deep to essentially the thickness of an entire wafer (>300 micrometers). However, each of these techniques has its limitations.

MEMS devices contain moving mechanical microstructures, typically exhibiting substantially three-dimensional geometries. An example of a process for bulk micromachined structures is described in U.S. Pat. No. 5,719,073 which is assigned to the assignee of the present application, the disclosure of which is hereby incorporated herein by reference. This process uses a single mask layer and appropriate etch and deposition steps to create a fully self-aligned, metalized bulk micromachined structure. Reactive ion etching is used to define and undercut an array of cantilever beams, which are connected together in order to form a more complete functional microstructure. All structure elements and interconnects are formed with the same masking layer, and isotropic dry etch techniques are used to release the structural layer. A modification to the '073 patent resulted in the invention described in U.S. Pat. No. 5,426,070, the disclosure of which is hereby incorporated herein by reference, is also assigned to the assignee of the present invention.

What is needed are improved micromachine manufacturing methods, and improved micromachine devices.

### SUMMARY OF THE INVENTION

The present invention provides a fabrication process that integrates high-aspect-ratio silicon structures with polysilicon surface micromachined structures. The process retains not only the high-aspect-ratio silicon structures possible with deep reactive ion etching (DRIE) but also the design flexibility of polysilicon surface micromachining. Using this process, polysilicon platforms have been fabricated, which are actuated by high-aspect-ratio combdrives for many applications such as x-y-z stages and scanning devices. The actuators include an asymmetric combdrive that actuates in torsional/out-of-plane motions, and a high-aspect-ratio combdrive that drives in translational motion.

Some embodiments provide a microphone and a method for forming a directional microphone having a proof mass and a membrane. The method includes (a) providing an SOI (silicon-on-insulator) starting wafer that has a single-crystal silicon substrate and that has a surface silicon layer of the thickness for the proof mass; (b) forming an oxide block on the top surface, including: (i) deep etching to form beam structures; (ii) performing a thermal oxidation; (iii) oxide refilling using low pressure chemical vapor deposition (LPCVD), and (iv) chemical-mechanical polishing (CMP). Notes: (1) Thermal oxidation enlarges the dimension of layout, and (2) A thin oxide on top of the top silicon layer functions as the mask for step (c)(i). Next, the method includes (c) forming a membrane, including: (i) etching the single-crystal silicon reserved for formation of corrugation, (ii) window etching for the thin-film (e.g., polysilicon) membrane anchored onto the top silicon layer, and (iii) depositing a thin-film deposition; and (d) backside-etch releasing, including: (i) single-crystal all-through etching from the backside of the wafer, and (ii) hydrofluoric acid (HF) releasing.

Another aspect of the present invention provides a micromachining technology and its variations that integrate DRIE bulk silicon micromachining with surface silicon (thin-film not limited to silicon) micromachining. The key to the processes is to make wafer surface conditions smooth enough for subsequent surface micromachining after bulk silicon micromachining using the formation of a sacrificial oxide block. The oxide block formation starts with the etching of closely spaced trenches in the silicon layer of the SOI wafer. Thermal oxidation transforms the remaining silicon into silicon dioxide. Finally, LPCVD oxide is deposited to refill the trench openings and after planarization the oxide block is created.

This micromachining technology has been applied to manufacture devices such as micromirrors with asymmetric combdrives, micromirrors with asymmetric combdrives and parallel-plate actuators, flipped-out micromirrors with combdrives, suspended inductors, and directional micromachined microphones. The following section describes the devices we fabricated and their fabrication processes.

Another aspect of the present invention provides a fabrication process that integrates polysilicon surface micromachining and DRIE bulk silicon micromachining. It takes advantage of the design flexibility of polysilicon surface micromachining and the deep silicon structures possible with deep reactive ion etching (DRIE). A torsional actuator driven by a combdrive moving in the out-of-plane direction, including polysilicon fingers and bulk silicon fingers, has been fabricated. The integrated process allows the combdrive to be integrated with any structure made by polysilicon surface micromachining. It is found that the driving voltage needed for the combdrive to torsionally actuate a 200 μm by 200 μm membrane is less than that needed for a parallel-plate actuator by at least 30 percent.

### BRIEF DESCRIPTION OF THE DRAWINGS

FIG. 1A is an SEM of a fabricated asymmetric-combdrive actuated membrane device 100.

FIG. 1B is a close-up SEM of a fabricated asymmetric-combdrive actuated membrane device 100.

FIG. 1C is a close-up SEM of a fabricated high-aspect ratio (symmetric) combdrive actuated membrane device 190.

FIG. 1D is a isometric schematic diagram of the operation of an asymmetric-combdrive actuated membrane device 100.

FIG. 1E is a top view schematic an asymmetric-combdrive actuated membrane device 100.

FIG. 1F is an SEM of a fabricated high-aspect ratio (symmetric) combdrive actuated membrane device 190.

FIG. 1G is a top view schematic a meandering-type torsional spring 1079 usable in asymmetric-combdrive actuated membrane device 100.

FIG. 2 is an SEM of a fabricated dually actuated membrane device 200.

FIG. 3 is a graph of experimental and simulation results of dual actuations.

FIG. 4 is an SEM of a silicon-scanning mirror 471 actuated by high-aspect-ratio combdrives made using DRIE.

FIG. 5 is an SEM of a micromachined on-chip suspended high-Q copper inductor 500.

FIG. 6 is an SEM of a cross-section of the coil 500 of FIG. 5 showing copper encapsulation 1246 of a 1.5 μm thick polysilicon freestanding beam 1241.

FIG. 7 is a graph of measured Q-factor versus frequency of inductor 500.

FIG. 8A is an SEM of a micromachined microphone 800.

FIG. 8B is a cross-section view of SEM of a micromachined microphone 800.

FIG. 9 is a graph of the frequency response of the micromachined microphone tested with 45 degrees incident sound.

FIG. 10 (which includes FIGS. 10(a) through 10(i)) schematically depicts schematic cross-sectional views of one process sequence used to fabricate the membrane and asymmetric combdrives.

FIG. 11 (which includes FIGS. 11(a) through 11(e)) schematically depicts schematic cross-sectional views of one process sequence used to fabricate lower electrodes 212.

FIG. 12 (which includes FIGS. 12(a) through 12(f2)) shows schematic cross-sectional views of the structure of wafer 1201 as a suspended inductor 1245 is made.

FIG. 13 (which includes FIGS. 13(a) through 13(f)) shows schematic cross-sectional views of the structure of wafer 1301 as a directional micromachined microphone 800 is made.

FIG. 14 (which includes FIGS. 14(a) through 14(j)) shows schematic cross-sectional views of the resulting wafer at each step of the process. The process began with a SOI wafer 1301 that had a to

### DESCRIPTION OF PREFERRED EMBODIMENTS

In the following detailed description of the preferred embodiments, reference is made to the accompanying drawings that form a part hereof, and in which are shown by way of illustration specific embodiments in which the invention may be practiced. It is understood that other embodiments may be utilized and structural changes may be made without departing from the scope of the present invention.

The leading digit(s) of reference numbers appearing in the Figures generally corresponds to the Figure number in which that component is first introduced or primarily discussed, such that the same reference number is used throughout to refer to an identical component which appears in multiple Figures. Signals and connections may be referred to by the same reference number or label, and the actual meaning will be clear from its use in the context of the description.

Definitions:

Integrated silicon micromachining (forming and shaping very small structures, optionally forming multiple structures simultaneously, and integrating different structures on a single silicon substrate),

DRIE (deep reactive ion etching),

MEMS (microelectromechanical systems)

SOI (silicon on insulator; a silicon layer, typically polycrystaline silicon (also called polysilicon), formed on an insulator such as SiO₂)

SEM (scanning electron micrograph image)

LPCVD (low pressure chemical vapor deposition)

high-aspect-ratio (a relatively thick height with respect to a width),

polysilicon surface micromachining (micromachining of polycrystaline silicon formed on the surface of a wafer based on silicon).

Surface silicon micromachining using sacrificial etching and bulk silicon micromachining utilizing deep reactive ion etching (DRIE) have given tremendous impetus to the field of microelectromechanical system (MEMS). DRIE silicon micromachining is a fabrication technique that produces high-aspect-ratio structures in a silicon substrate. The movable deep structures are created by the formation of undercut. A major advantage of the process is the excellent mechanical properties of single-crystal silicon. However, the process has strict geometric limitations on structure designs—use of uniform cross-section beams, difficulty with the integration of in-plane membranes, and inability to fabricate multiple-level structures with various features (e.g. hinge).

In contrast, surface silicon micromachining creates micromechanical structures from deposited thin films which are free to move after the underlying sacrificial material is removed. A three-dimensional (3D) polysilicon structure can be built by folding out the surface structures. However, some characteristics such as electrostatic output force, resonant frequency, and capacitive sensing signal suffer from the limitation on the thickness of deposited thin film.

Since the merits and demerits of DRIE high-aspect-ratio silicon micromachining and surface silicon micromachining are in general complementary, it is desirable to combine them. Integration of these two techniques not only retains the advantages of individual method but also increases the designer's freedom for structure designs.

There are three possible integration approaches of surface micromachining (not limited to silicon) and bulk silicon micromachining. One is refill of sacrificial materials (not limited to silicon dioxide) into the cavities due to bulk silicon micromachining on wafers and followed by wafer planarization for subsequent surface micromachining. Another method is to create a feasible wafer condition by bonding another wafer onto the wafer done by bulk micromachining and grinding it to the desired thickness. The other choice is to fabricate the surface micromachined structures on one side of wafers (not limited to silicon-on-insulator (SOI) wafers) and to process the bulk micromachined structures on the other side.

I. Embodiment #1—An Integrated Thin Film (Polysilicon) and DRIE Bulk Silicon Micromachining (See Method I for the Process Flow)

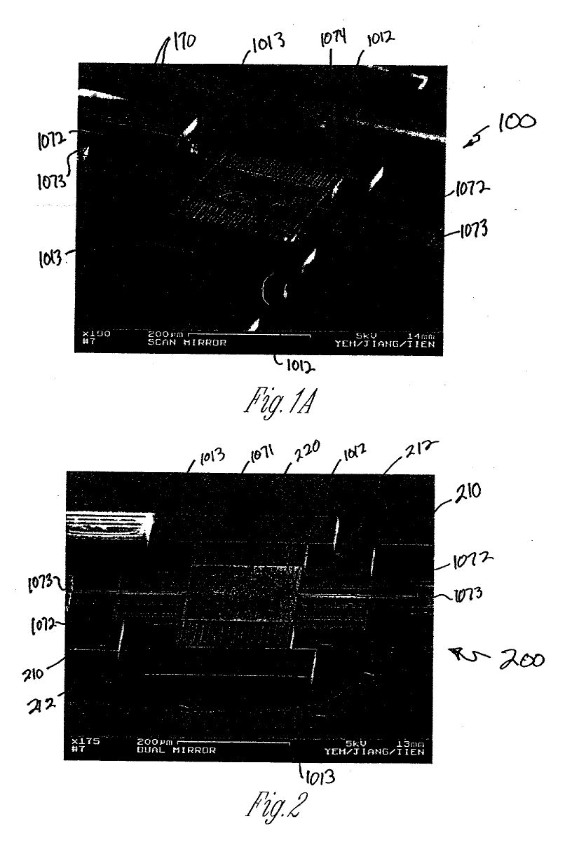

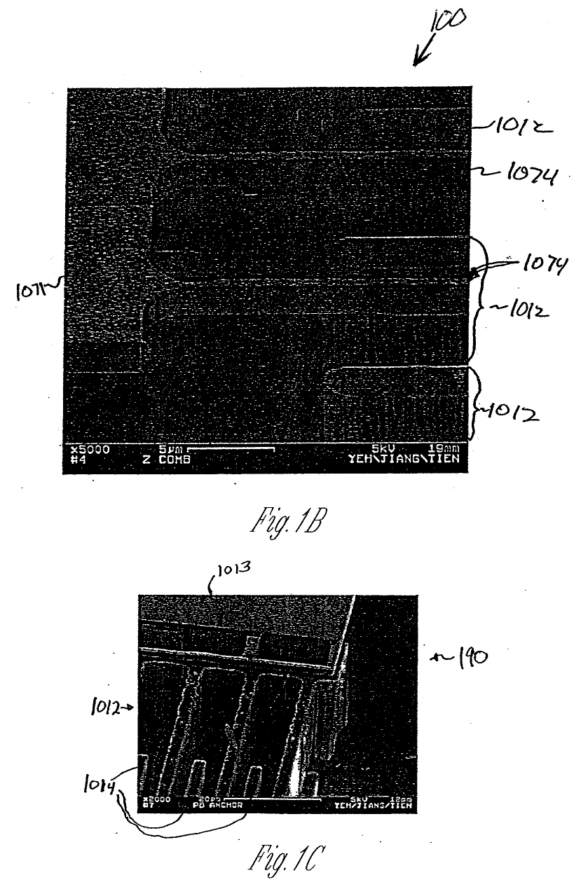

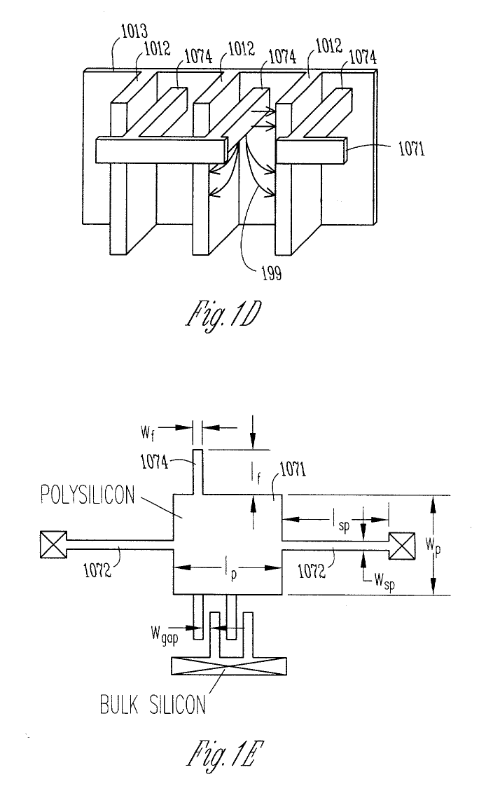

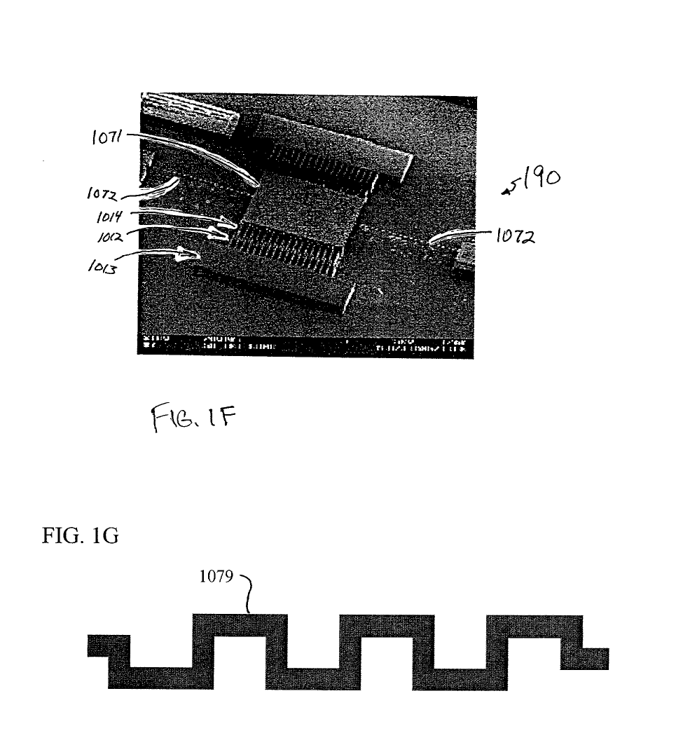

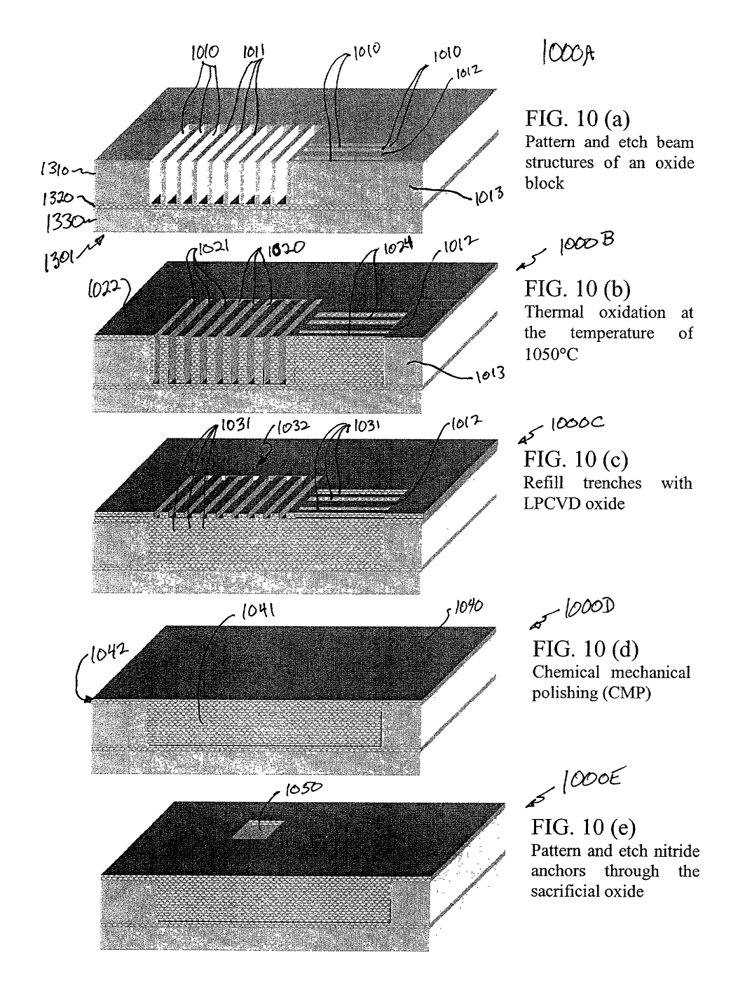

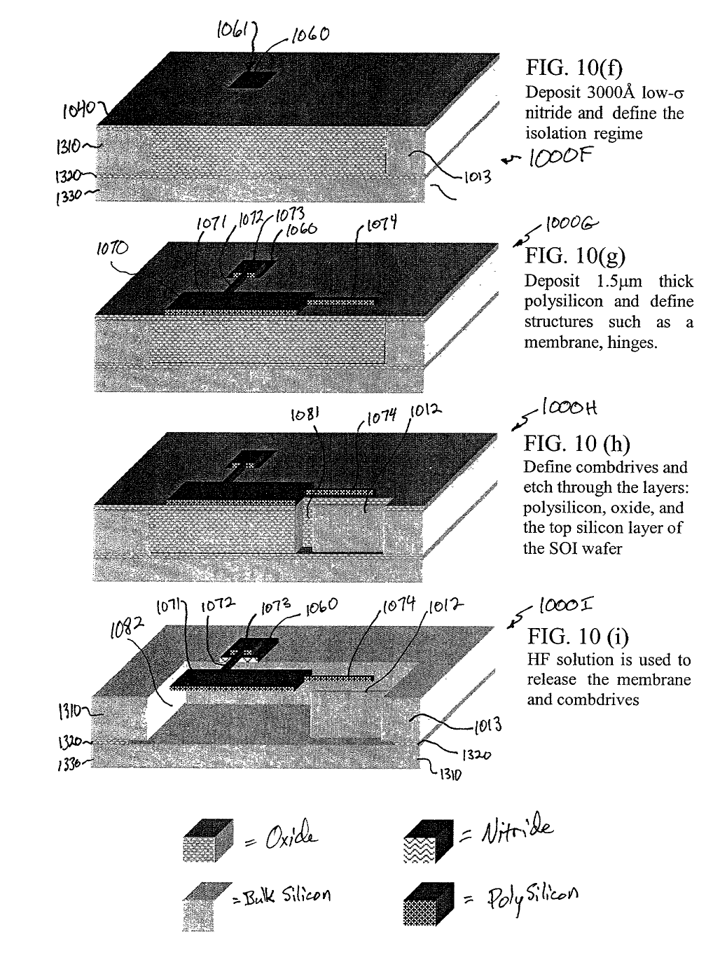

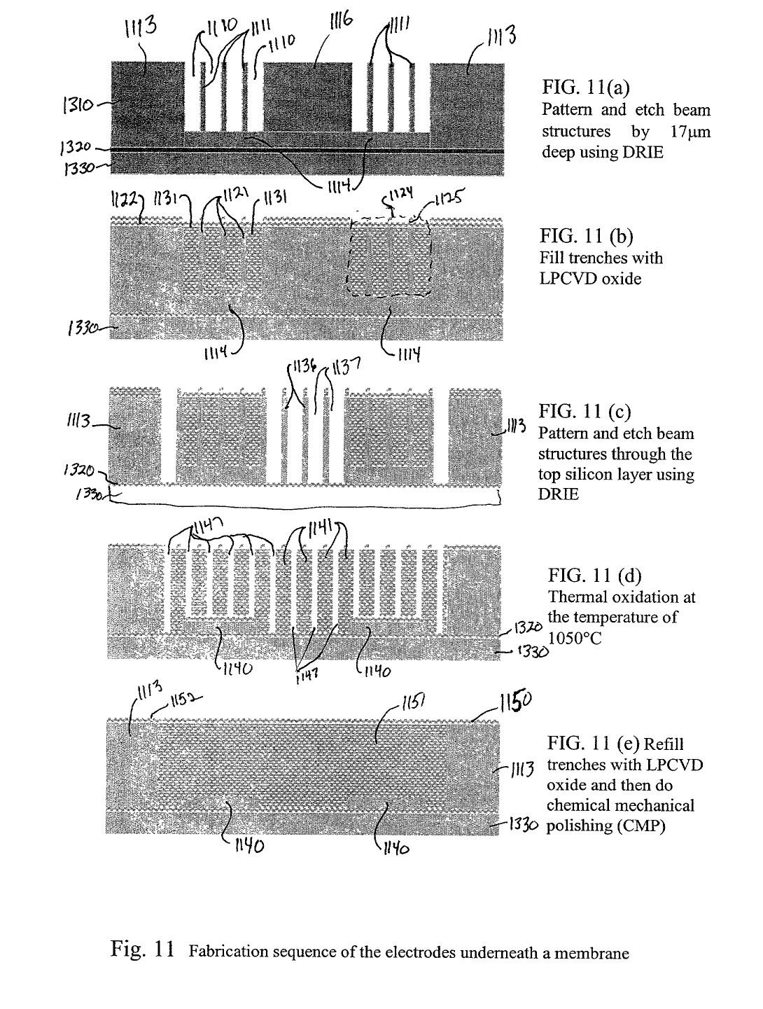

FIG. 1A is an SEM of a fabricated asymmetric-combdrive-actuated membrane device 100. Device 100 uses asymmetric combdrives 170 to actuate a polysilicon membrane 1071 in torsional motion. The membrane 1071 is 200 μm by 200 μm and its attached springs 1072 are 200 μm long and 2 μm wide from the top view, and extend to platform pads 1073. Both the membrane 1071 and the springs 1072 are fabricated from polysilicon 1070 (see FIG. 10) of thickness 1.5 μm. The induced fringing electric field lines on one-side of the asymmetric combdrives 170 generate a downward force and a torque on the polysilicon suspension springs 1072. In some embodiments, membrane 1071 forms a micromirror. The force lowers the position of the micromirror with respect to the anchored end of the springs, while the torque causes an into-plane rotational motion of the micromirror, allowing it to twist around the polysilicon torsional springs 1072.

Movable polysilicon comb fingers 1074 and fixed high-aspect-ratio silicon comb fingers 1012 form the asymmetric combdrives 170. Unlike a conventional combdrive, where the fingers of both combs are of the same thickness and in the same plane, the polysilicon fingers 1074 of the asymmetric combdrives are thinner and higher (they are normally in plane above the tops of fingers 1012) than the fixed comb fingers 1012. Actuation is achieved when the thin polysilicon fingers 1074 are pulled downward toward the substrate with respect to the fixed thick bulk silicon fingers 1012 under a voltage applied between the comb of fingers 1074 and the comb of fingers 1012. The pull-down of the movable comb (fingers 1074) is the result of fringing electric field, on the polysilicon fingers 1074, which creates torsional motion. The asymmetry in height and thickness of comb fingers causes a net fringing capacitance that points down into the substrate.

FIG. 1B is a close-up SEM of a fabricated asymmetric-combdrive actuated membrane device 100. Thick high-aspect ratio fixed fingers 1012 extend downwards about 20 μm, while moving fingers 1074 are thinner, only about 1.5 μm, and are pulled downward (down in FIG. 1B) between fingers 1012.

FIG. 1C is a close-up SEM of a fabricated high-aspect ratio (symmetric) combdrive actuated membrane device 190. Thick high-aspect ratio fixed fingers 1012 extend downwards about 20 μm, as do moving fingers 1014, and are pulled sideways between fingers 1012 (up and left in FIG. 1C).

FIG. 1D is a isometric schematic diagram of the operation of an asymmetric-combdrive actuated membrane device 100. Electrostatic force 199 pulls fingers 1074 down and between fixed fingers 1012.

FIG. 1E is a top view schematic an asymmetric-combdrive actuated membrane device 100. In some embodiments, the torsional angle of deflection is enhanced by increasing the length lₛₚ of spring 1072 and/or decreasing its width wₛₚ. In some embodiments, the torsional angle of deflection is enhanced by increasing the length l_{f} of fingers 1074 and/or decreasing the gap between fingers w_{gap}. In some embodiments, this is accomplished by increasing the width w_{f} of moving fingers 1074.

FIG. 1F is an SEM of a fabricated high-aspect ratio (symmetric) combdrive actuated membrane device 190.

FIG. 1G is a top view schematic small section of a meandering-type torsional spring 1079 used in some embodiments of asymmetric-combdrive actuated membrane device 100, in place of spring 1072. This design provides a smaller torsional force from the spring 1079, thus allowing greater deflection angles of mirror 1071.

II. Embodiment #2—Multiple Depths of Silicon Etches Using DRIE (See Method II, below, for the Process Flow)

FIG. 2 is an SEM of a fabricated dually actuated membrane device 200. Device 200 has silicon parallel-plate electrodes 212 of width 85 μm that is 20 μm below the membrane 1071, in addition to the structures of device 100 shown in FIG. 1(a). The membrane 220 and its underlying electrodes 212 can be used either as a parallel-plate actuator (an output device wherein the membrane moves due to an input electrical signal from signal traces 210) or as a capacitive sensor (wherein the membrane moves due to an externally created capacitance, and creates a signal or signal change to signal traces 210). The only difference between the process creating device 100 of FIG. 1(a) and the process that creates the device 200 of FIG. 2 is that the process for device 200 with underlying electrodes 212 takes one more etch step (see FIG. 11) to form oxide blocks (later removed) of two different depths. The etch holes 220 are used to speed up the wet etch release of the structures, and, in some embodiments, such etch holes 220 are also used in device 100 of FIG. 1(a) and other membranes described herein.

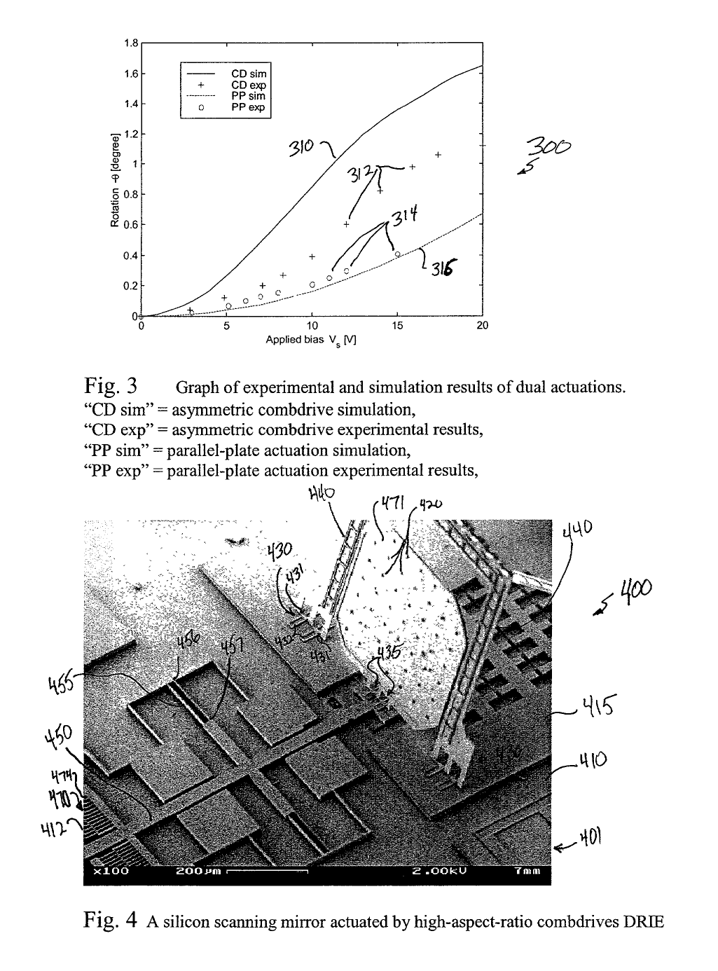

Device 200 has been used to compare the performance of torsional motion actuated by asymmetric combdrives 170 to torsional motion actuated by parallel-plate actuators 212. Both experimental and simulation data of the static response to DC bias are shown in FIG. 3. It is found that the fabricated asymmetric combdrive 170 generates a larger rotational angle than the parallel-plate actuator under an equal applied voltage. In one embodiment, the bottom electrodes 212 and top electrodes (i.e., membrane 1071) are separated from each other by a vertical gap of 20 μm, and the gap between the polysilicon fingers 1074 and bulk silicon fingers 1012 measured 4.2 μm from the top view. Under a fifteen-volt DC bias, the measured rotational angles of the membrane when actuated by the combdrive and the parallel-plate actuator were 0.95 degree and 0.41 degree, respectively. The maximum rotation actuated by asymmetric combdrives 170 was measured to be 1.14°, which corresponds to the vertical deflection of 3.6 μm at the ends of the movable fingers 1074. In fact, the maximum of the measured rotation is much smaller than the theoretical value of 2.6 degrees at 36 volts.

FIG. 3 is a graph of experimental and simulation results of dual actuations. Line CD sim 310 represents asymmetric combdrive simulation, points CD exp 312 represent asymmetric combdrive experimental results, line PP sim 316 represents parallel-plate actuation simulation, and points 314 PP exp represent parallel-plate actuation experimental results.

III. Embodiment #3—Multiple Silicon (Thin-Film) Structural Layers on Top of DRIE Bulk Silicon Micromachined Structures on a SOI Wafer (See Method III for the Process Flow)

FIG. 4 is an SEM of a silicon-scanning mirror actuated by high-aspect-ratio combdrives made using DRIE. A flipped-out scanning mirror 471 was fabricated using a variation of this integrated micromachining technology. The mirror 471 is suspended at its vertical edge midpoints by two short torsion springs to two rectangular bars 440 that are attached to the frame 415 with hinges 430. High-aspect-ratio silicon combdrives 470 push and pull a shuttle 450 translationally, actuating the mirror 471 torsionally through the hinges 435 that connect the shuttle 450 and the mirror 471. The shuttle 450, the combdrives 470 (including full height fixed comb 412 and full height interdigitated moving comb 472 that moves lower left to upper right in FIG. 4, and folded springs (thin vertical walls 455 attached to fixed anchor points 456 and to shuttle anchor 457) are fabricated out of single-crystal silicon of the top layer 1310 of an SOI wafer 401.

IV. Embodiment #4—Multiple Silicon (Thin-Film) Layers on Top of DRIE Bulk Silicon Micromachined Structures on a Regular Silicon Wafer (See Method IV for the Process Flow)

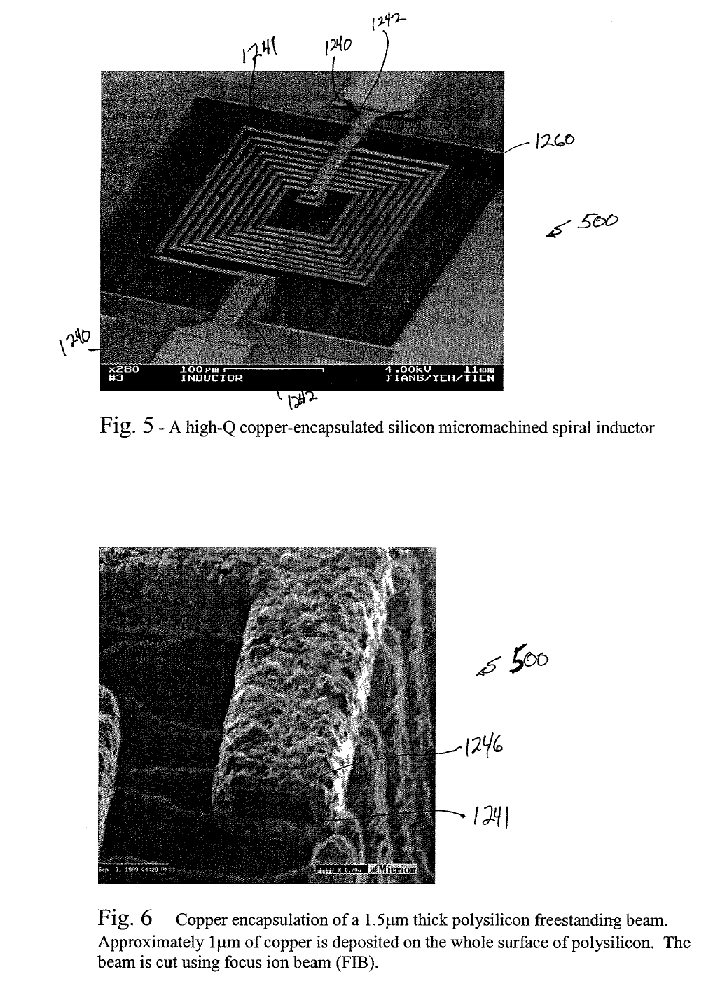

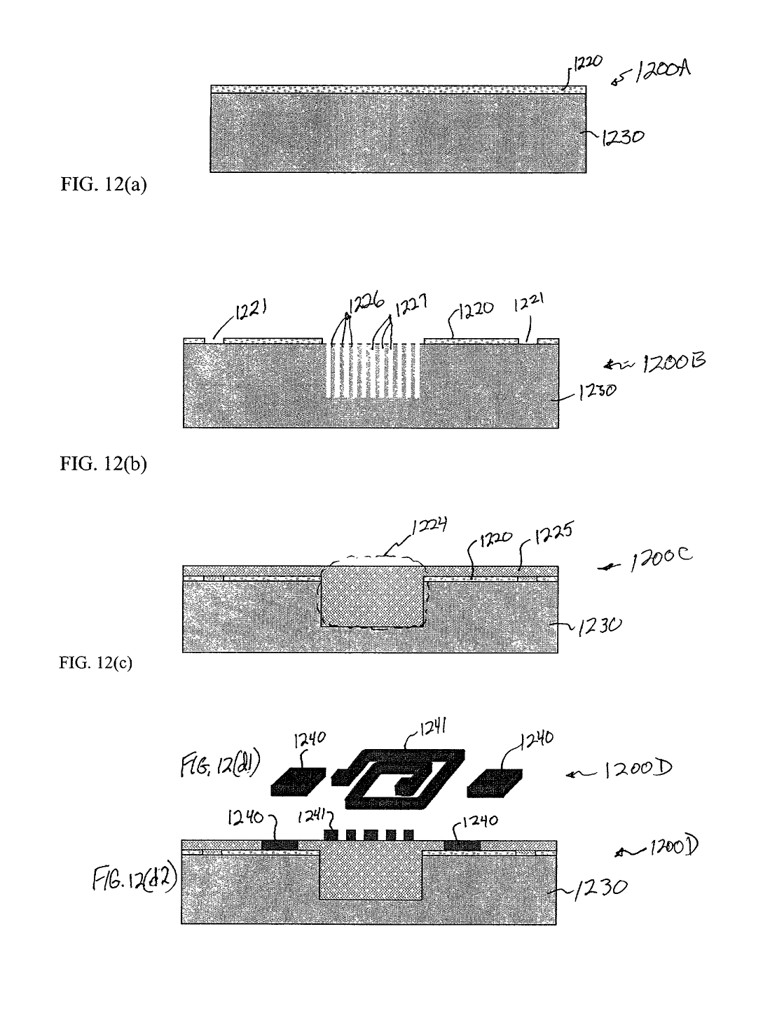

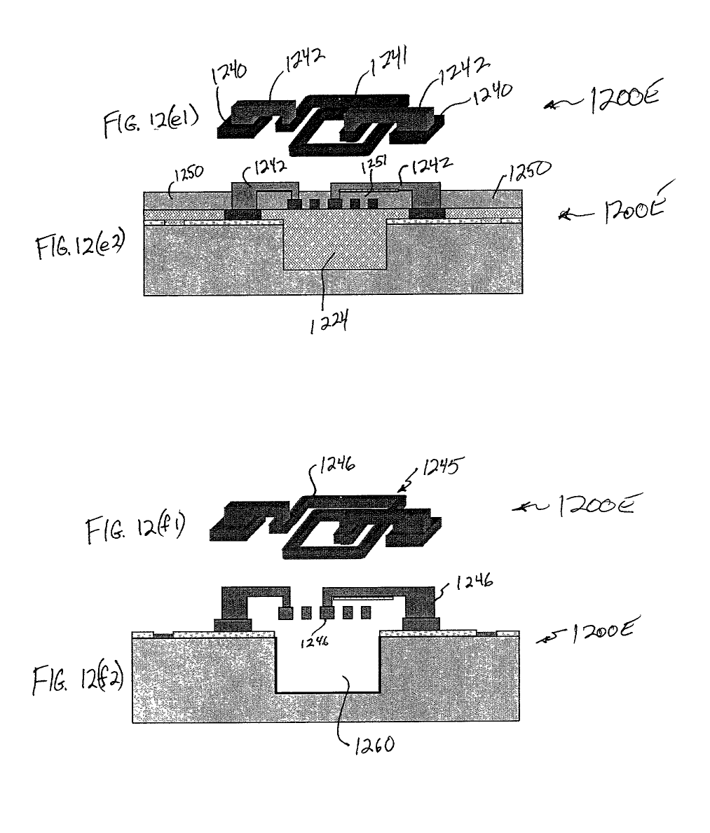

FIG. 5 is an SEM of a high-quality-factor (high-Q) copper-encapsulated on-chip suspended silicon micromachined spiral inductor 500. Polysilicon was used to build the spiral structure 1241 of the inductor 500 that is suspended over a 30 μm deep cavity 1260 in the silicon substrate 1201 beneath. The cavity 1260 is created with the formation of an oxide block (see 1224 of FIG. 12), followed by HF release (hydrofluoric acid etch) after the device fabrication. After the HF release, copper 1246 was electrolessly plated onto the polysilicon spiral 1241 to achieve low resistance (see FIG. 6). The plating process also metallized the inner surfaces of the cavity 1260 to provide both a good radio-frequency (RF) ground and an electromagnetic shield.

FIG. 6 is a close-up SEM of a cross-section of the coil 500 of FIG. 5 showing copper encapsulation 1246 of a 1.5 μm thick polysilicon freestanding beam 1241. Approximately 1 μm of copper is deposited on the whole surface of polysilicon. For this picture, the beam 1241 was cut using a focused ion beam (FIB).

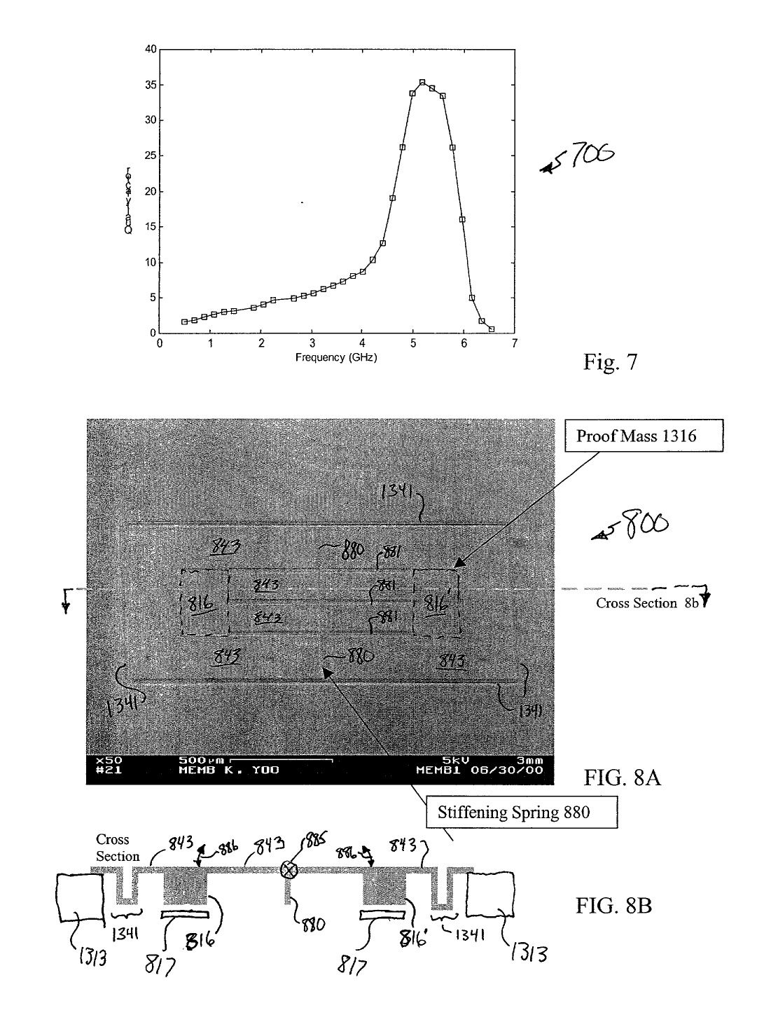

In one embodiment, an inductor with the nominal inductance of 3.17-nH was fabricated and tested. It includes five turns; the line width after Cu plating is 4 μm; the line-to-line spacing is 4 μm; the length of the innermost strip is 125 μm; the thickness of the deposited Cu is found to be 1.5 μm and its resistivity measured to be 2.1 μQ-cm. Based on an equivalent lumped-element π-model, the Q curve of the 3.17-nH inductor is determined by the ratio of the imaginary to the real part of its measured short-circuit input impedance, and is plotted in FIG. 7. As is shown, the maximum Q is as high as 36 at a frequency of 5.2 GHz. The self-resonant frequency, where Q drops to zero, is found to be 6.6 GHz.

FIG. 7 is a graph 700 of measured Q-factor versus frequency of the 3.17-nH inductor 500 of FIG. 5.

V. Embodiment #5—with Backside Processing (See Method V for the Process Flow)

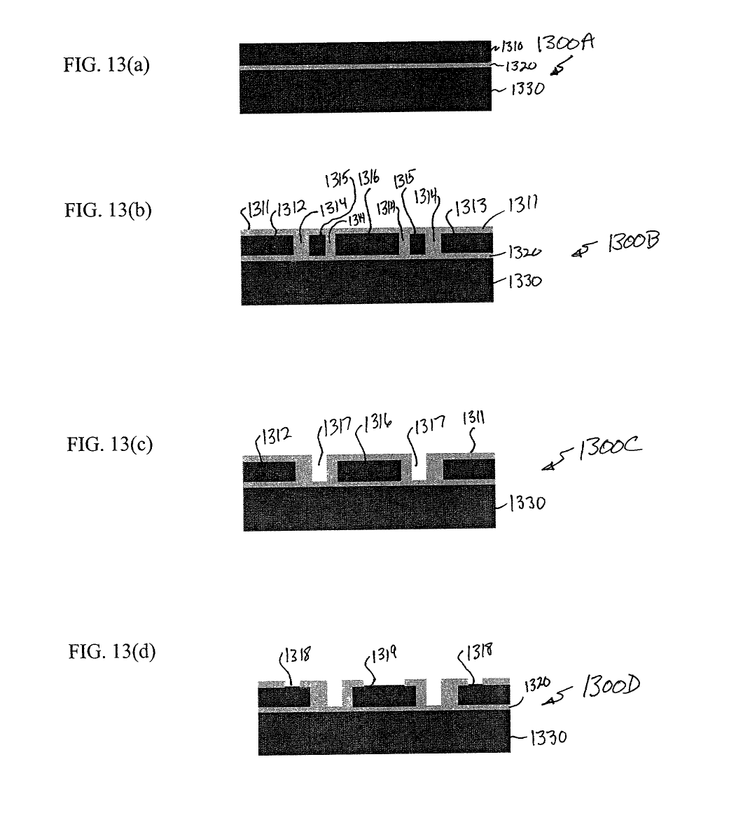

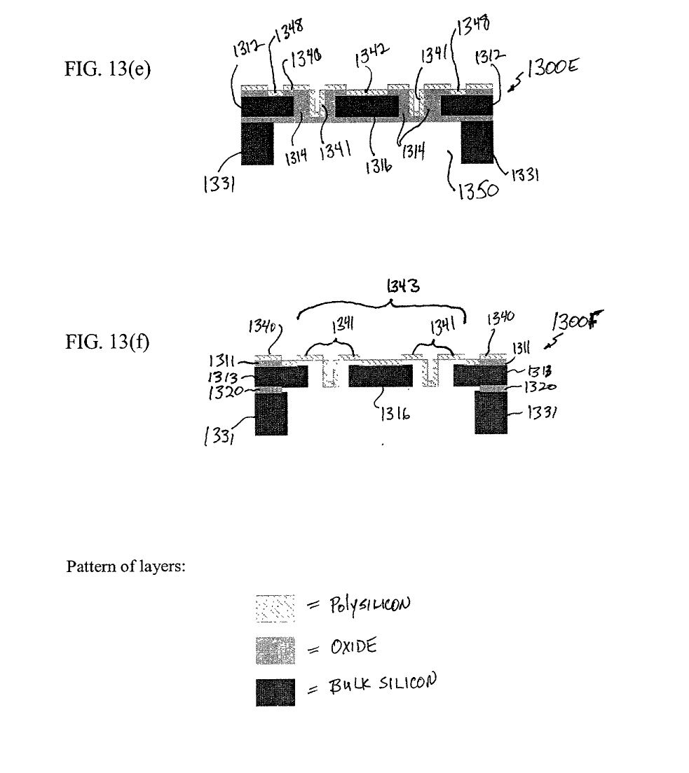

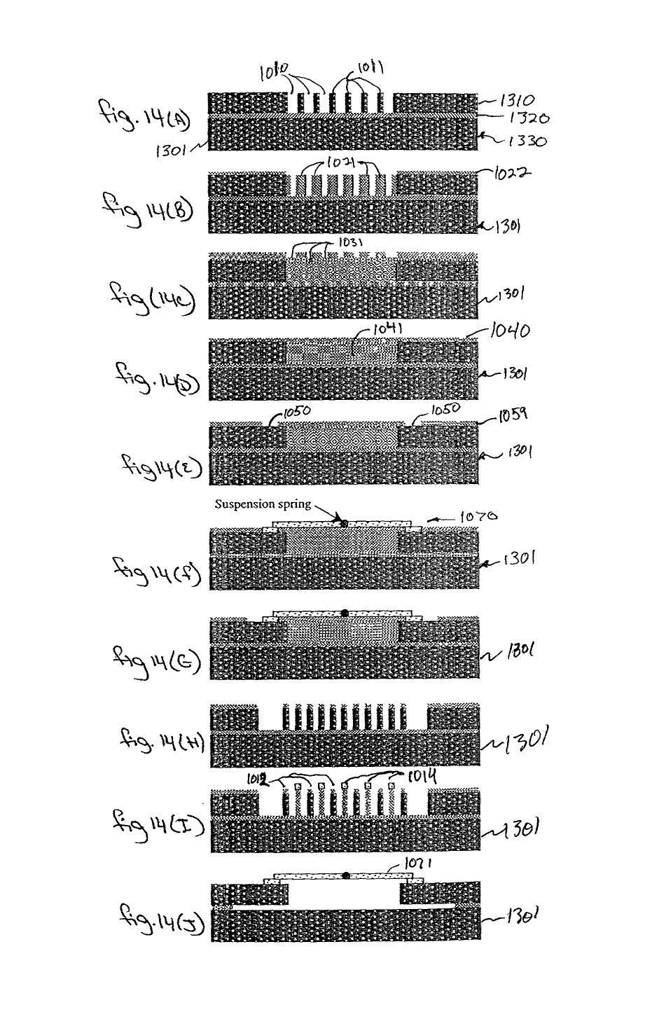

FIG. 8A is an SEM picture of micromachined microphone 800. The present invention's fabrication process has another variation that was used to manufacture directional micromachined microphone 800. The micromachined microphone 800 includes a sealed polysilicon membrane 843 that has a plurality of proof-mass blocks 816 and 816′ (made of single-crystal silicon of the top silicon layer 1310, see FIG. 13). In some embodiments, membrane 843 is supported at its periphery by support 13113, and capacitive sensors 817 under the proof masses 816 are separately used to detect motions of the proof masses 816.

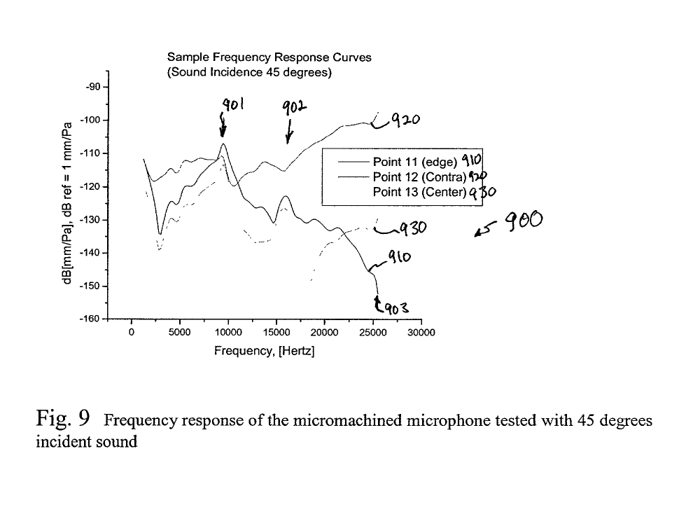

In some embodiments, proof-mass blocks 816 and 816′ are joined to one another by vertical stiffening bars 881 which are bisected by stiffening spring 880 to gain the directivity, and corrugations 1341 of depth 20 μm that releases the stress imposed on the membrane 843. Stiffening bars 881 permit a rocking motion 886 of proof masses 816 and 816′ that pivots along an axis 885 defined by stiffening spring 880. The measured test results 900 (see FIG. 9) show that the device 800 has the rocking mode 902 occurring at 16.5 kHz and the in-phase mode 903 occurring at 25.0 kHz. In some embodiments, a signal derived from the rocking motion and another signal derived in-phase motions are analyzed using well known techniques to derive an indication of direction. In some embodiments, a hearing aid includes a directional microphone 800 and circuitry that enhances audio signals from a particular direction, in order to enhance, e.g., intelligibility of voices.

FIG. 9 is a graph of the frequency response 900 of the micromachined microphone 800 tested with 45 degrees incident sound. The first peak response 901 at about 10,000 Hz and the second peak response 902

### REFERENCES

Additional background material may be found in:

J. -L. A. Yeh, C. -Y. Hui and N. C. Tien “Electrostatic Model for an Asymmetric Combdrive,” IEEE/ASME Journal of Microelectromechanical Systems (JMEMS), vol. 9, pp. 126-135, March 2000.

J. -L. A. Yeh, H. Jiang and N. C. Tien, “Integrated Polysilicon and DRIE Bulk Silicon Micromachining for a Torsional Actuator,” Journal of Microelectromechanical Systems (JMEMS), vol. 8, pp. 456-465, December 1999.

H. Jiang, J. -L. A. Yeh, Y. Wang and N. C. Tien, “Electromagnetically Shielded High-Q CMOS Compatible Copper Inductors,” in Digest of Technical Papers International Solid-State Circuits Conference (ISSCC '00), San Francisco, Calif., Feb. 7-9, 2000, pp. 330-331.

J. -L. A. Yeh, H. Jiang and N. C. Tien, “Fabrication of Polysilicon Platforms Actuated by High-aspect-ratio Silicon Combdrives,” in Proc. of Abstracts The 13^{th} European Conference on Solid-State Transducer (Eurosensor XIII), Hague, Netherlands, Sep. 12-15, 1999, pp. 15-16.

Method I

One process sequence used to fabricate the membrane and asymmetric combdrives is depicted schematically in FIG. 10 (which includes FIGS. 10(a) through 10(i)). The following is a description of fabrication process (version 1) used, in some embodiments, to manufacture a micromirror with asymmetric combdrives. An SOI (silicon-on-insulator) wafer 1301 was provided that had a 20 μm-thick silicon layer 1310 on top of a 1 μm-thick buried oxide 1320 on top of a single-crystal silicon substrate 1330. First, a plurality of trenches 1010 were etched in the top silicon layer 1310 with a DRIE etcher (PlasmaTherm SLR770) using photoresist as the mask. Trenches 1010 were 2 to 3 μm wide, 1 μm apart (leaving a plurality of 1 μm-wide beams 1011) and 20 μtm deep (see FIG. 10(a)). In addition, a plurality of thicker beams 1012 are formed by a wider spacing of their surrounding trenches 1024. (Only one such beam is shown in these cutaway views of FIG. 10.) The beams 1011 were completely thermally oxidized at a temperature of 1050° C.; the thermal oxidation transformed silicon into silicon dioxide, resulting in a slightly larger oxide block (having oxidized beams 1021 and trenches 1020) than the dimension in the design (see FIG. 10(b)). This oxidation step only partially oxidizes beams 1012, leaving a central beam of silicon on each beam 1012 that later forms half of the comb drive.

Following the oxidation step, the open trenches 1020 between the fully oxidized beams 1021 were filled with conformal LPCVD oxide 1031 (formed at a rate of 4 nm/min@900° C.), resulting in ripples 1032 on the oxide surface (see FIG. 10(c)).

These ripples 1032 were then planarized with chemical-mechanical polishing (CMP) (see FIG. 10(d)), leaving a smooth top surface 1040. The combination of thermally grown oxide and deposited oxide served as an oxide block 1041 for the subsequent surface micromachining. The oxide block formation transformed the unwanted single-crystal silicon in top layer 1310 into silicon dioxide, which will be removed in the final step of structure release. The formation sequence of one layer of the oxide block is illustrated in FIGS. 10(a)-(d). In other embodiments, additional layers of oxide block and additional mechanisms can be added using similar processes, as is well known in the art.

In some embodiments, conventional polysilicon surface micromachining is subsequently performed on top of the wafer (see FIG. 10(d)). The oxide block 1041 helps maintain a flat surface across the substrate for the following thin film processing. A 1.1 μm thick LPCVD oxide layer 1042 was deposited to form the first sacrificial layer. Windows 1050 were dry etched in the LPCVD oxide 1042 with a fluorine-based etcher so that afterwards a low-stress nitride and polysilicon deposition could be anchored onto the substrate (see FIG. 10(e)). A 250 nm low-stress nitride layer 1061 was deposited to be used as an isolation layer between the polysilicon 1070 and the top silicon layer 1310 of the SOI wafer 1301. This layer was then photolithographically patterned and etched (see FIG. 10(f)) to leave a nitride pad 1060 in window 1050.

The structural layer 1070 is 1.5 μm thick LPCVD in-situ boron-doped polysilicon deposited at a temperature of 620° C. (see FIG. 10(g)). The polysilicon layer 1070 was used to form the structures such as membrane 1071 and springs 1072, and used to provide the material for the movable fingers 1074 of the asymmetric combdrives 170 which were etched in the final deep etch. This layer 1070 was anchored onto a stationary bulk silicon piece. A 450 nm overlay oxide (not shown) was deposited and thermally annealed at the temperature of 1000° C. for one hour. The deposited oxide was patterned and used as a hard mask for etching the polysilicon 1070 underneath with a chlorine-based etcher. Another 350 nm oxide (also not shown) was subsequently deposited to serve as a hard mask for the single-crystal silicon structure etch.

Following the thin-film processing, a final mask was used to pattern the top silicon layer 1310 on the SOI wafer 1301 and the thin-film layers on top of it (see FIG. 10(h)). For example, in some embodiments, in the formation of the asymmetric combdrives 170, both the bulk silicon fingers 1012 and the polysilicon fingers 1074 are defined in the same lithographic step, to prevent lateral misalignment between the two combs which would severely degrade the performance of the combdrives 170. With one mask (not shown), the fingers 1074 in the polysilicon layer and the remaining silicon portions of fingers 1012 in single-crystal silicon layer 1310 are etched sequentially. Underneath the polysilicon fingers 1074, the unwanted single-crystal silicon was previously transformed to oxide, which is removed later. This process step makes use of fluorine-based, chlorine-based and Bosch-process etchers to etch the layers of sacrificial oxide, polysilicon and single-crystal silicon, while the buried oxide 1320 of the SOI wafer functions as the etch-stop layer. Rapid thermal annealing (RTA) was performed at the temperature of 1100° C. for one minute to reduce the interfacial stresses between different materials. Finally, the silicon micromachined structures were released using a hydrofluoric acid (HF) solution to remove all the sacrificial oxide leaving an empty underspace 1082 beneath membrane 1071, torsion spring supports 1072, and moving fingers 1074 (see FIG. 10(i)).

One reason for separating the polysilicon etch into two parts, where the final etch was used for the formation of the movable fingers of the combdrive is to simplify the formation of the polysilicon structures and to gain the maximum dimensional control of the structures. In addition, the separation of the etches allowed us to avoid design limitations such as having the polysilicon finger structures 1074 be the same dimension as the underlying single-crystal silicon finger structures 1012.

Method II

FIG. 11 (which includes FIGS. 11(a) through 11(e)) schematically depicts one process sequence used to fabricate buried structures 1114 that can be used as lower electrodes 212. The following is a description of fabrication process (version 2) used to manufacture a micromirror with asymmetric combdrives and parallel-plate actuators (the polysilicon membrane and bottom electrodes underneath the membrane).

A few process steps (see FIG. 11) are added in addition to the process delineated in Method I. To fabricate device 200, an SOI wafer is provided that has a 20 82 m thick silicon layer 1310 on top of a 1 μm thick buried oxide 1320, which is formed on a substrate 1330. First, we created the bottom electrodes 212 of a parallel-plate actuator out of the top silicon layer of the SOI wafer on top of oxide layer 1320. Trenches 1110 that were etched in the top silicon layer with a DRIE etcher, using photoresist as the mask, were 2 to 3 μm wide, 1 μm apart and 17 μm deep (see FIG. 11(a)), leaving about 3 μm of silicon 1114, and 1 μm-wide sacrificial beams 1111. The remaining 3 μm single-crystal silicon 1114 was kept for the two underlying plates (electrodes) 212 parallel to the substrate surface 1330.

The deposition of low-temperature oxide (LTO) 1131 (30 nm/min@400° C.) covered the deep trench openings 1110 and smoothed the silicon surface for the next photolithographic step (see FIG. 11(b)). The LTO 1131 also served as a hard mask for the next deep etch where the buried oxide of the SOI wafer was the etch stop layer. The 17 μm thick silicon posts 1111 on top of the underlying electrodes 1114 were protected by the upper portion of deposited LTO 1125 from the deep etch process, which created trenches 1137 that were 20 μm in depth, and which created the silicon beam structures 1136 for the oxide block 1151 (see FIG. 11(c) and 11(e)). To avoid single-crystal silicon residue within the oxide block due to beams in different steps, we overlapped the trench structures. The purpose of the second deep etch is to form the oxide block around and between the bottom electrodes 1114 and under polysilicon structures (e.g., membrane 1071 of FIG. 2(a)). A short HF dip was taken to remove the deposited LTO remaining around the beam structures. Thermal oxidation at the temperature of 1050° C. completely transformed the silicon beams 1136 to silicon dioxide 1141 (see FIG. 11(d)). Conformal LPCVD oxide was deposited to fill the open trenches 1147 between the fully oxidized beams 1141 and then the resultant bumpy oxide surface was planarized by CMP to form a smooth top surface 1150 across the entire wafer, including over oxide block 1151, (see FIG. 11(e)). The rest of the fabrication procedure after the formation of the oxide block is the same as described above in Method I.

Method III

The following is a description of fabrication process (version 3) used to manufacture device 400 (see FIG. 4) having a flipped-up micromirror 471 with high-aspect-ratio combdrives 470. The distinction between this Method III and the process described in Method I is that two layers of polysilicon were deposited after the formation of oxide blocks, followed by a DRIE etching step.

After the formation of oxide blocks (such as block 1151 of FIG. 11), a 1.5 μm low-temperature oxide (LTO) 1152 is deposited at the temperature of 400° C. as the first sacrificial layer. Dimples and anchor openings (see 1050 of FIG. 10) are lithographically transferred into the sacrificial layer with a CHF₃-based plasma etcher. Another 2.5 μm in-situ phosphate-doped polysilicon layer is deposited and functions as the first structural material (poly1). Poly1 layer is used for the flipped-up structures such as mirror 471, bars 440, and hinge pins 431. An annealing step is performed at 1000° C. for one hour in N₂ to reduce the residual stresses built in the poly1, which is subsequently etched using oxide as a hard mask. A second LTO sacrificial layer of a thickness 1.5 μm is deposited and etched for the formation of anchor openings (for anchoring the hinge straps 432 to the base) and poly1-poly2-vias. A 1.5 μm thick n-type polysilicon layer is deposited, patterned and etched to form the second structural layer (poly2). Poly 2 is used for hinge straps 432 that cover the moving hinge pins 431 and attach to the top silicon layer 1310. The last step of fabrication is to pattern and etch high-aspect-ratio structures (such as combdrives 470 of FIG. 4) in the top silicon layer 1310 of the SOI wafer 1301.

Method IV

FIG. 12 (including FIGS. 12(a) through 12(f2)) shows the structure of wafer 1201 as a suspended inductor 1245 (such as in device 500 of FIG. 5) is made. The following is a description of fabrication process (version 4) used to manufacture a suspended inductor. The process flow is described as follows.

First, as shown in FIG. 12(a), a silicon nitride layer 1220 is deposited as the isolation layer on a silicon substrate 1230 to form wafer 1200A. Then, sacrificial oxide blocks 1224 that define the cavities are created in the silicon substrate 1230. This is done by the following steps: etching 30 μm deep narrow beam 1226 and trench 1227 structures, as shown in FIG. 12(b), using deep reactive ion etching (DRIE); thermally oxidizing the beams and depositing silicon oxide as described above, and planarizing the surface with chemical mechanical polishing (CMP) resulting in the wafer 1200C as shown in FIG. 12(c). Next, the inductors 1245 are created, using one patterned polysilicon layer 1200D as the coils (see the device 1200D in the isometric view of FIG. 12(d1) and the side view of FIG. 12(d2)) and another patterned polysilicon layer (see the device 1200E in the isometric view of FIG. 12(e1) and the side view of FIG. 12(e2)) used as the overpasses 1242 that suspend the coil 1245 and pass the signal. A thin silicon nitride layer 1253 is also grown under the second polysilicon layer wherever it crosses over either the coil or the cavity edges to ensure isolation. Finally, (see the device 1200F in the isometric view of FIG. 12(f1) and the side view of FIG. 12(f2)) the structure 1245 is released in hydrofluoric (HF) acid and electroless Cu plating is performed. The exposed silicon and polysilicon structures are plated with Cu as shown in FIG. 4, while those areas covered with silicon oxide and silicon nitride remain intact, providing good isolation.

In some embodiments, the following process is used:

a) Silicon nitride isolation layer deposition

b) Opening for metal routing and creating the beam-trench structures for the formation of silicon oxide block

c) Creating the oxide block by thermal oxidation, silicon oxide deposition and CMP

d) Definition of the inductor by growing, patterning and etching the first polysilicon layer

e) Growth of the second sacrificial silicon oxide layer and creating overpasses by patterning the second polysilicon layer

f) HF release of the sacrificial silicon oxide and electroless Cu deposition

Method V

FIG. 13 (including FIGS. 13(a) through 13(f)) shows the structure of wafer 1301 as a directional micromachined microphone 800 is made. The following is a description of fabrication process (version 5) used to manufacture a directional micromachined microphone.

In some embodiments, the following process is used:

a) Start with a SOI (silicon-on-insulator) wafer 1301 that has a top silicon layer 1310 of the thickness for proof mass, an oxide layer 1320, and a silicon substrate 1330. See FIG. 13(a).

b) Form oxide blocks 1314 (the same as the integrated silicon process) See FIG. 13(b).

i) Deep etch to form beam structures (such as beams 1011 of FIG. 10(a))

ii) Thermal oxidation (forming silicon oxide beams such as beams 1021 of FIG. 10(b)

iii) LPCVD oxide refill (such as fill 1031 of FIG. 10C)

iv) Chemical-mechanical polishing (CMP) (such as FIG. 10(d)

Notes:

1) Thermal oxidation enlarges the dimension of layout, since the outer walls of the outer trenches are oxidized.

2) A thin oxide 1042 on top of the top silicon layer 1310 functions as the mask for step (c)(i) described below

c) Membrane formation

i) Etch the single-crystal silicon portions 1317 reserved for formation of corrugation. See FIG. 13(c).

ii) Window etch for the thin-film (e.g. polysilicon) membrane anchored onto the top silicon layer. Windows 1318 anchor the membrane 1343 to the outer top layer 1312, and window 1319 anchors the membrane 1343 to the proof mass(es) 1316. See FIG. 13(d).

iii) Thin film deposition of, e.g., a polysilicon layer 1340 which forms corrugations 1341 and membrane 1343 and substrate anchors 1348 and proof-mass anchor(s) 1342. See FIG. 13(e).

d) Backside etch release. See FIG. 13(f).

i) Single-crystal all-through etch from the backside of the wafer 1301 removes the portion of substrate 1330 between the side support 1331.

ii) Hydrofluoric acid (HF) release removes the oxide layer 1320 and oxide blocks 1314 within and behind the membrane 1343 and proof mass(es) 1316.

Comb Drive Additional Embodiments

DRIE silicon micromachining (see [1] S. Miller, K. Turner and N. C. MacDonald, “Microelectromechanical scanning probe instruments for array architectures,” Rev. Sci. Instrum., vol. 68, November 1997, p. 4155-4162; and [2] W. Juan and S. Pang, “Released Si microstructures fabricated by deep etching and shallow diffusion,” IEEE J. Microelectromechanical Systems, vol. 5, 1996, pp. 19-23) produces high-aspect-ratio structures in a silicon substrate. Movable deep structures are created through the use of undercut processes to separate the formed structure from the substrate on which it was formed. A major advantage of the process is the excellent mechanical properties of single-crystal silicon. Such a process, however, imposes strict geometric limitations on structure designs, including the need to form beams having a uniform cross section, difficulty with the integration of in-plane membranes, and inability to fabricate multiple-level structures with complex features, such as hinges.

In contrast, polysilicon surface micromachining (see [3] M. Rodgers and J. Sniegowski, “5-level polysilicon surface micromachine technology: application to complex mechanical systems,” Proc. Solid-State Sensor and Actuator Workshop '98, Hilton Head, S.C., USA, 1998, pp. 144-149) creates micromechanical structures from deposited thin films which are free to move after an underlying sacrificial material is removed. Structures, such as three-dimensional (3D) polysilicon structures, can be built by using a hinge and folding out the surface structures. However, some characteristics such as electrostatic output force, resonant frequency, and capacitive sensing signal suffer from the limitations on the thickness of the deposited thin film.

Since the merits and demerits of DRIE high-aspect-ratio silicon micromachining and polysilicon surface micromachining are in general complementary, it is desirable, according to the present invention, to combine them. Integration of these two techniques not only retains the advantages of each individual method, but also increases the designer's freedom to create new structures. The integrated process of the present invention can be used to fabricate structures similar to those of the original methods, as well as new mechanical components such as asymmetric combdrives, mixtures of beams and membranes, and tailored anisotropic springs such as T-shaped non-uniform-thickness springs.

Polysilicon Platform Actuated by a High-Aspect-Ratio In-Plane Combdrive in Translational Motion

FIG. 1(f) shows an exemplary device design that utilizes a high-aspect-ratio in-plane combdrive (the moving fingers 1014 are approximately the same height as fixed fingers 1012, and are interdigitated) to actuate a suspended polysilicon platform in translational motion (the platform slides side-to-side as an applied voltage pulls the moving fingers 1014 into further engagement with fixed fingers 1012). The device includes 20-μm-thick high-aspect-ratio in-plane combdrives and 1.5-μm-thick polysilicon springs that are compliant in the direction of displacement. The combination of thin springs and high-aspect-ratio combdrives can provide large displacements at low operating voltages. Longer and/or thinner springs (giving less torsion), and/or smaller spacings between the moving fingers 1074 and fixed fingers 1012, allow larger displacements and/or lower operating voltages. The compliant suspension system reduces the voltage bias needed to generate the same displacement, as compared to springs having the same thickness as the comb fingers.

Anchoring of the polysilicon platform onto the high-aspect-ratio combdrive made of single-crystal silicon is illustrated in FIG. 1(c). Formation of the anchor is achieved by the deposition of polysilicon through a window that is opened by etching through the sacrificial oxide. To enhance the structure release, the feature size of the structures that are created in the polysilicon embedded in the top silicon layer is limited, in some embodiments, to 5 μm in width.

Polysilicon Platform Actuated by an Asymmetric Combdrive in Torsional Motion

A polysilicon platform actuated by an asymmetric combdrive in torsional motion is shown in FIG. 1(a). The platform 1071 is suspended by polysilicon rectangular bars and is actuated by an asymmetric combdrive located at the ends of the platform. The asymmetric combdrive, shown in FIG. 1(a) and 1(c), includes thin movable polysilicon fingers 1074 and thick fixed high-aspect-ratio silicon fingers 1012. In the absence of applied voltage, the plane of moving fingers 1074 is above the top of fixed fingers 1012. The combdrive utilizes the fringing capacitance between the thinner and higher comb 1074 and the thicker and lower comb 1012 to generate a torque that allows the platform to twist around the polysilicon springs 1072 in torsional motion.

Typically, torsional motion is achieved using either a parallel-plate actuator (such as plates 212 acting on membrane 1071 of FIG. 2) or the fringing force of an in-plane interdigitated combdrive (fingers 1074 to fixed fingers 1012 of FIG. 2) (see [1] S. Miller, K. Turner and N. C. MacDonald, “Microelectromechanical scanning probe instruments for array architectures,” Rev. Sci. Instrum., vol. 68, November 1997, p. 4155-4162). An asymmetric combdrive is an alternative for actuating a device in torsional motion. The asymmetric combdrive has the advantages of large initial torque like an in-plane interdigitated combdrive and wide-range rotation like a parallel-plate actuator. A large rotation associated with proper torque generation can be achieved by appropriately choosing a set of geometric parameters—the thickness of movable fingers, the initial vertical position of movable fingers, the separation gap between the combs, etc. (see [4] J. -L. A. Yeh, N. C. Tien and C. -Y. Hui, “Electrostatic actuation of an asymmetric combdrive,” to be published).

One fabrication process for creating polysilicon platforms actuated by high-aspect-ratio silicon combdrives is depicted schematically in FIG. 14. FIG. 14 (which includes FIGS. 14(a) through 14(j)) shows the resulting wafer at each step of the process. The process began with a SOI wafer 1301 that had a top silicon layer 1310 of 20 μm and the buried oxide 1320 of 1 μm. A sacrificial oxide block 1041 in the top silicon layer 1310 was constructed prior to the polysilicon surface micromachining. The oxide block formation transformed the unwanted region of the top silicon layer to silicon dioxide that could be removed in the final step of structure release.

As shown in the cross-section view of FIG. 14(a) First, 1-μm-wide beams 1011 were created by etching trenches 1010 through the top silicon layer 1310 with a DRIE etcher using photoresist as the mask, while the buried oxide 1320 functions as an etch-stop layer (see FIG. 14(a)). The trench openings 1020 between the beams were 2-3 μm wide, in order to avoid physical contact between the sidewalls of two adjacent beams. Next, the beams 1011 were completely thermally oxidized at a temperature of 1050° C.; the thermal oxidation transformed single-crystal silicon to silicon dioxide beams 1021. Consumption of silicon during the thermal oxidation led to a slightly larger oxide block than the dimension in the design (see FIG. 14(b)).

Following the oxidation step, conformal LPCVD oxide 1031 was deposited at a temperature of 900° C. to fill the open trenches between the fully oxidized beams (see FIG. 14(c)). The oxide deposition resulted in ripples on the oxide surface that were then planarized with chemical-mechanical polishing (CMP) (see FIG. 14(d)). The combination of thermal oxide and deposited LPCVD oxide served as an oxide block 1041 that helped maintain a flat surface 1040 across the substrate 1301 for the succeeding surface micromachining.

Conventional polysilicon surface micromachining was subsequently performed on top of the wafer after the oxide block formation. LPCVD oxide 1059 was deposited to make the sacrificial layer of thickness 1.1 μm. Windows 1050 were dry etched in the sacrificial oxide with a fluorine-based etcher so that subsequent polysilicon deposition could be anchored onto the top silicon layer (see FIG. 14(e)).

The structural layer is 1.5 μm thick LPCVD in-situ boron-doped polysilicon 1070 deposited at a temperature of 620° C. (see FIG. 14(f)). The polysilicon layer 1070 was used to form the structures such as the membrane 1071 and springs 1072, and used to provide the material for the movable fingers 1074 of the asymmetric combdrives 170 which were etched in the final deep etch. This layer 1070 was anchored onto a stationary bulk silicon piece through windows 1050. A 450 nm overlay oxide (not shown) was deposited and thermally annealed at the temperature of 1000° C. for one hour. The deposited oxide was patterned and used as a hard mask for etching the polysilicon 100070 underneath with a chlorine-based etcher.

Following the thin-film processing, a final mask was applied to create different types of electrostatic actuators including high-aspect-ratio in-plane combdrives and asymmetric combdrives (see FIG. 14(g)). 350 nm LPCVD oxide was deposited to serve as a hard mask for the single-crystal silicon structure etch where the buried oxide functioned as the etch stop layer. To fabricate the high-aspect-ratio in-plane combdrives, a DRIE etch was performed to shape the comb structure in the top silicon layer while the polysilicon above the combdrives was removed in the previous polysilicon etch (see FIG. 14(h)).

In the formation of the asymmetric combdrives, both the bulk silicon fingers and the polysilicon fingers were defined in the same lithographic step to prevent lateral misalignment between the two combs which would severely degrade its performance (see FIG. 14(i)). With one mask, the fingers in the polysilicon layer and single-crystal silicon layer were etched sequentially. Underneath the polysilicon fingers the unwanted single-crystal silicon had previously been transformed to oxide. This process step makes use of fluorine-based, chlorine-based and Bosch-process (see [7] F. Laermer and A. Schilp, “Method of anisotropically etching silicon,” U.S. Pat. No. 5,501,893, filed on Aug. 5, 1994, which is incorporated by reference) etchers to etch the layers of sacrificial oxide, polysilicon and single-crystal silicon.

After the sequence of etches and depositions, rapid thermal annealing (RTA) was performed at the temperature of 1100° C. for one minute to reduce the interfacial stresses between different materials. Finally, the silicon micromachined structures were released using a hydrofluoric acid (HF) solution to remove all the sacrificial oxide (see FIG. 14(j)).

It is straightforward to integrate more layers of polysilicon with the DRIE high-aspect-ratio silicon structures. In the process presented here, one polysilicon layer and one single-crystal silicon layer were utilized for the formation of movable structures. The integrated process used to create two movable polysilicon layers has even more design flexibility so that elements like the folded-out 3D structures can be created (see [6] R. S. Muller and K. Y. Lau, “Surface-micromachined microoptical elements and systems,” Proc. IEEE, August 1998, pp. 1705-1720). A thick single-crystal silicon layer can provide large force output, high resonant frequency or heavy proof mass.

A major advantage of the integrated process is the elimination of mechanical coupling, mostly in the folded-out 3D devices. For example, a hinge can transfer energy forwards and backwards between translational motion and rotational motion. The instability caused by this coupling can be avoided by the separation of the dynamic responses of the different structure components that are connected by a hinge. The frequency separation can be achieved by fabricating the components using different micromachining techniques that have their own inherent dynamic performances.

DRIE bulk silicon micromachining is a fabrication technique that allows one to produce deep structures in a silicon substrate or even movable structures by formation of undercuts. Many fabrication methods have been used to make microstructures out of single-crystal silicon, including Single-Crystal silicon Reactive ion Etch And Metallization (SCREAM) process (see [1A] K. A. Shaw, Z. L. Zhang, and N. C. MacDonald, “SCREAM I: A single mask, single-crystal silicon process for microelectromechanical structures,” in Proc. IEEE Micro electro Mechanical systems Workshop (MEMS '93), Fort Lauderdale, Fla., 1993, pp. 155-160), deep-etch shallow-diffusion process (see [2A] W. H. Juan and S. W. Pang, “Released Si microstructures fabricated by deep etching and shallow diffusion,” IEEE J. Microelectromech. Syst., vol. 5, pp. 19-23, 1996), and silicon-on-insulator (SOI) process. These techniques have several common advantages such as excellent mechanical properties and high-aspect-ratio structures. However, there exist geometric constraints to the types of structures that can be fabricated; some examples are limitations on the maximum width of released beams, difficulty with the integration of membranes parallel to the substrate, and inability to create multiple-level structures with various features (e.g., hinges).

The purpose of polysilicon surface micromachining is to fabricate micromechanical structures from deposited thin films. Polysilicon structures anchored to the silicon ground plane are free to move after the underlying sacrificial material is removed. Multiple layers of structural polysilicon and sacrificial layers can be sequentially deposited and patterned in order to realize complex and multi-layered structures (see [3] M. Rodgers and J. Sniegowski, “5-level polysilicon surface micromachine technology: application to complex mechanical systems,” in Proc. IEEE Solid State Sensors and Actuators Workshops (Hilton Head '98), June 1998, pp. 144-149). Three-dimensional polysilicon structures can be built by folding out the surface structures. Various types of actuators such as the electrostatic interdigitated combdrive (see [4] W. C. Tang, T. -C. H. Nguyen, M. W. Judy, and R. T. Howe, “electrostatic combdrive of lateral polysilicon resonators,” Sens. Actuators, vol. A21-23, pp. 328-331, 1990), the scratch device actuator (SDA) (see [5] T. Akiyama and K. Shono, “Controlled stepwise motion in polysilicon microstructures,” IEEE J. Microelectromech. Syst., vol. 2, no. 3, pp. 106-110, 1993), and the thermal actuator (see [6] H. Guckel, J. Klein, T. Christenson, K. Skrobis, M. Laudon, and E. Lovell, “Thermo-magnetic metal flexure actuators,” in Proc. IEEE Solid State Sensors and Actuators Workshops (Hilton Head '92), June 1992, pp. 73-75) have been developed to move these microstructures. However, the thinness of the deposited polysilicon film can limit aspects of the device performance such as capacitive sensing signal, electrostatic force and resonant frequency. In addition, the use of polysilicon brings up some material and fabrication issues that do not appear in bulk micromachining processes such as residual stress, stress gradient through the film, variation of Young's modulus, topography with multiple-layer structures, and in-use/release stiction.

Both DRIE bulk silicon micromachining and polysilicon surface micromachining have merits and demerits when used alone. However, many limitations of one method can be overcome by the other. Integrated polysilicon and DRIE bulk silicon micromachining not only retains the advantages of both methods but also expands the range of structure designs. In addition to the structures that can be made by the individual methods, combinations of surface and bulk methods can be applied to build actuators such as combdrives with fingers asymmetric in height and thickness, parallel-plate actuators, anisotropic springs, and mixtures of beams and membranes. Furthermore, the resonant frequencies of these structures can be designed to be far apart from each other by having them made using either polysilicon surface micromachining or DRIE bulk silicon micromachining. The separation of resonant frequencies benefits structural stability and reduces coupling between structures.

To demonstrate the feasibility of integrated polysilicon and DRIE bulk silicon micromachining, we have fabricated an electrostatic torsional actuator driven by an asymmetric combdrive which generates a torque on a polysilicon membrane. Unlike a conventional combdrive where the fingers of both combs are of the same thickness and in the same plane, the distinction of the combdrive we present is that the fingers on one comb are thinner and higher than those on the other comb. Actuation is achieved when the thin polysilicon fingers are pulled downward toward the substrate with respect to the fixed thick bulk silicon fingers under a voltage applied between the combs. The pull-down of the movable comb (i.e., fingers 1074), shown in FIG. 1(a), is the result of fringing electric field on the polysilicon fingers which creates torsional motion. The asymmetry in height and thickness of comb fingers causes a net fringing capacitance that points down into the substrate. Note that the actuator's differential capacitance varies with the position of the movable polysilicon fingers. Hence, this combdrive cannot generate a constant output torque due to its position-dependent differential capacitance.

Present approaches for producing torsional motion by electrostatic actuators include parallel-plate actuators (see [7] K. E. Peterson, “Silicon torsional scanning mirror,” IBM J. Res. Develop., vol. 24, no. 5, 1980, pp. 631-637; [8] L. Hornbeck, “Current status of the digital micromirror device (DMD) for projection television applications,” in Proc. IEEE Int. Electron Devices Meeting, Washington, D.C., December 1993, pp. 381-384; and [9] D. L. Dickensheet and G. S. Kino, “Silicon-micromachined scanning confocal optical microscope,” IEEE J. Microelectromech. Syst., vol. 7, no. 1, pp. 38-47, 1998), in-plane interdigitated combdrives utilizing the out-of-plane fringing force (see [10] S. A. Miller, K. L. Turner, and N. C. MacDonald, “Microelectromechanical scanning probe instruments for array architectures,” Rev. Sci. Instrum., vol. 68, November 1997, p. 4155, 4162; and 11. W. C. Tang, M. G. Lim, and R. T. Howe, “electrostatic comb drive levitation and control method,” IEEE J. Microelectromech. Syst., vol. 1, no. 4, pp. 170-178, 1992), and in-plane interdigitated combdrives used to swing structures such as a plate connected to it by a hinge. An example is the folded-up scanning mirrors driven by combdrives (see [12] M.-H. Kiang, O. Solgaard, K. Y. Lay, and R. S. Muller, “Electrostatic combdrive-actuated micromirror for laser-beam scanning and positioning,” IEEE J. Microelectromech. Syst., vol. 7, no. 1, pp. 27-37, 1998; and 13. N. C. Tien, M. -H. Kiang, M. J. Daneman, O. Solgaard, K. Y. Lau, and R. S. Muller, “Actuation of polysilicon surface-micromachined mirror,” SPIE 1996 International Symposium on Lasers and Optoelectronics, San Jose, Calif., vol. 2687, 1996, pp. 53-59). In those structures, dynamic problems such as coupling, backlash and low resonant frequency can be encountered. Coupling between torsional and translational motions results in the instability of the device. Backlash occurs at the moment when the direction of motion is changing because of the clearance between the pin and the staple. In devices where torsional motion can be generated by in-plane interdigitated combdrives, the maximum angle of rotation is limited.

Typically, large rotational motion is archived using a parallel-plate actuator. Asymmetric combdrives fabricated by integrated polysilicon and DRIE bulk silicon micromachining are an alternative that offers better dynamic performance for a large rotational motion. The static and dynamic performance of a parallel-plate actuator and our combdrive are discussed in section IV. It is found that a membrane will twist at a lower operating voltage with this asymmetric combdrive than with a parallel-plate actuator.

With our new technology, we have fabricated a device 100, shown in FIG. 1(a), that uses these combdrives to actuate a polysilicon membrane in torsional motion. Also, we have created another device 200, shown in FIG. 2, that has additional silicon parallel-plate electrodes 212 underneath the membrane. The membrane 1071 and its underlying electrodes 212 can be used either as a parallel-plate actuator or as a capacitive sensor. In some embodiments, one side is used as an actuator by applying a electrostatic voltage, and the other side is used as a capacitive sensor or feedback device, and is driven with a small AC sensing signal whose frequency (dependent on the capacitance that varies with deflection) is detected. Both devices are fabricated on a SOI wafer 1301. The bulk fingers 1012 and underlying electrodes 212 are fabricated from the top silicon layer of the SOI wafer. On top of the SOI wafer, surface micromachining is used to form the polysilicon structures.

In some embodiments, the polysilicon membrane 1071, shown in FIG. 2, is suspended by a pair of rectangular bars 1072 and is actuated by our asymmetric combdrive 170. In some embodiments, the membrane is used as a scanning micromirror. The scanning micromirror has many applications such as optical memories, video projection, laser-beam positioning or scanning, laser-beam steering, and fiber-optic switching (see [8] L. Hornbeck supra; [9] D. L. Dickensheet et al, supra; [12] M. -H. Kiang et al, supra; 13. N. C. Tien et al., supra; and 14. H. Toshiyoshi and H. Fujita, “electrostatic micro torsion mirrors for an optical switch matrix,” IEEE J. Microelectromech. Syst., vol. 5, no. 4, pp. 231, 1996). Two sets of combdrives are placed, one at each edge of the micromirror, parallel to the substrate. The torsional springs 1072, micromirror 1071, and movable fingers 1074 of the combdrive are made of polysilicon. The top silicon layer 1310 of the SOI wafer 1301 is used to form the fixed fingers 1012 of the combdrive. The induced fringing electric field lines, shown in FIG. 1(d), on one side of the combdrive generates a pull-down force and a torque on the polysilicon springs 1072. The force lowers the position of the micromirror edge with respect to the anchored end of the springs, while the torque causes an into-plane rotational motion of the micromirror, allowing it to twist around the polysilicon torsional springs 1072.

A device 200 consisting of the previous structure and additional parallel plates is shown in FIG. 2. The parallel plates 202 can be used for precise sensing and control of angular motion and position. This device 200 can be driven by both actuators or only one while the other actuator is used as a sensor to form an internal feedback loop. In some embodiments, either the asymmetric combdrive or the parallel-plate actuator are used to provide the rotational motion of the micromirror, while the other can be employed as a differential capacitive sensor to detect angular changes. This feedback system can be applied to control either angular position or angular velocity of a micromirror.

One process sequence used to fabricate the membrane and asymmetric combdrives is depicted schematically in FIG. 14. In this process, the mechanical structures were built not only from thin films deposited on top of the silicon surface but also in the top silicon layer of a SOI wafer. The key to this process is the formation of a sacrificial oxide block prior to the polysilicon surface micromachining (see [15] H. B. Erzgraber, Th. Grabolla, H. H. Richter, P. Schley, and A. Wolff, “A novel buried oxide isolation for monolithic RF inductors on silicon,” in Proc. International Electron Devices Meeting (IEDM '98), December 1998, pp. 535-539). The oxide block is formed by etching closely spaced trenches in the silicon layer of the SOI wafer. Thermal oxidation transforms the remaining silicon into silicon dioxide. LPCVD oxide is deposited to refill the trench openings and after planarization the oxide block is created.

This approach to the formation of the oxide block has several advantages over deposited oxide refilling of wide and deep trenches. First, only a few μm thick oxide deposition is required for the trench opening refill no matter what the depth is because of the closely spaced thermal oxide posts. Furthermore, a thinner film deposition results in a smoother topography on the wafer making planarization easier. In addition to the process advantages, a thin oxide deposition also reduces the induced moment acting on the substrate that is caused by the stress distribution through the film which depends on the film thickness. A large bending moment would severely bend the wafer. The residual stress and built-in stress gradient of a thick deposited oxide may also crack the oxide film. In general, the problems caused by stress distribution within the deposited thin films are highly dependent on the film thickness and greatly reduced with our technique.

On top of the silicon wafer, one layer of structural polysilicon was deposited to form the membrane, torsional bars, and one side of the fingers of the asymmetric combdrive. On the other side of the combdrive, fingers made by single-crystal silicon were patterned and etched together with the polysilicon fingers using a single mask to avoid misalignment of the comb fingers. After completion of the structures, the oxide block are removed with hydrofluoric acid (HF).

For the device with bottom electrodes underneath the polysilicon membrane, which are formed from single-crystal silicon, more fabrication procedures are needed. To fabricate this device 200, shown in FIG. 2, were began with a SOI wafer that had a 20 μm thick silicon layer on top of a 1 μm thick buried oxide. First, we created the bottom electrodes of a parallel-plate actuator as shown in FIG. 11. Trenches that were etched in the top silicon layer with a DRIE etcher (PlasmaTherm SLR770) using photoresist as the mask, were 2-3 μms wide, 1 μm apart and 17 μm deep. The remaining 3 μm single-crystal silicon was kept for the two underlying plates (electrodes) parallel to the substrate surface. The deposition of low-temperature oxide (LTO) (30 nm/min@400° C.) covered the deep trench openings and smoothed the silicon surface of the next photolithographic step. The LTO also served as a hard mask for the next deep etch where the buried oxide of the SOI wafer was the etch stop layer. The 17 μm thick silicon posts on top of the underlying electrodes were protected by the deposited LTO from the deep etch which was 20 μm in depth, and which created the silicon beam structures for the oxide block. To avoid single-crystal silicon residue within the oxide block due to beams in different steps, we overlapped the trench structures. The purpose of the second deep etch is to form the oxide block around the bottom electrodes and under polysilicon structures.

The beams were completely thermally oxided at a temperature of 1050° C.; the thermal oxidation transformed silicon to silicon dioxide resulting in a lightly larger oxide block than the dimension in the design. Following the oxidation step, the open trenches between the fully oxidized beams were filled with conformal LPCVD oxide (4 nm/min@900° C.) resulting in ripples on the oxide surface. These ripples were then planarized with chemical-mechanical polishing (CMP). The combination of thermally grown oxide and deposited oxide served as an oxide block for the subsequent surface micromachining. The oxide block formation transformed the unwanted single-crystal silicon to silicon dioxide which could be removed in the final step of structure release. The formation sequence of one layer of the oxide block is illustrated in FIGS. 11(a)-11(d), as described above.

Conventional polysilicon surface micromachining was subsequently performed on top of the wafer. The oxide block helped maintain a flat surface across the substrate for the following thin film processing. A 1.1 μm thick LPCVD oxide layer was deposited to form the first sacrificial layer. Windows were dry etched in the LPCVD oxide with a fluorine-based etcher so that afterwards a low-stress nitride and polysilicon deposition could be anchored onto the substrate. A 250 nm low-stress nitride layer was used as an isolation layer between the polysilicon and the top silicon layer of the SOI wafer. This layer was then photolithographically patterned and etched.

The structural layer is 1.5 μm thick LPCVD in-situ boron-doped polysilicon deposited at a temperature of 620° C. The polysilicon layer was used to form the structures such as membrane and springs, and used to provide the material for the movable fingers of the asymmetric combdrives which were etched in the final deep etch. This layer was anchored onto a stationary bulk silicon piece. A 450 nm overlay oxide was deposited and thermally annealed at the temperature of 100° C. for one hour. The deposited oxide was patterned and used as a hard mask for etching the polysilicon underneath with a chlorine-based etcher. Another 350 nm oxide was subsequently deposited to serve as a hard mask for the single-crystal silicon structure etch.

Following the thin-film processing, a final mask was used to pattern the top silicon layer on the SOI wafer and the thin-film layers on top of it. For example, in the formation of the asymmetric combdrives, both the bulk silicon fingers and the polysilicon fingers were defined in the same lithographic step to prevent lateral misalignment between the two combs which would severely degrade its performance. With one mask, the fingers in the polysilicon layer and single-crystal silicon layer were etched sequentially. Underneath the polysilicon fingers, the unwanted single-crystal silicon was previously transformed to oxide. This lithographic step makes use of fluorine-based, chlorine-based and Bosh-process etchers to etch the layers of sacrificial oxide, polysilicon and single-crystal silicon while the buried oxide of the SOI wafer functions as the etch stop layer. Rapid thermal annealing (RTA) was performed at the temperature of 1100° C. for one minute to reduce the interfacial stresses between different materials. Finally, the silicon micromachined structures were released using a HF solution to remove all the sacrificial oxide.

The reason for separating the polysilicon etch into two parts where the final etch was used for the formation of the movable fingers of the combdrive is to simplify the formation of the polysilicon structures and to gain the maximum dimensional control of the structures. In addition, the separation of the etches allowed us to avoid design limitations such as having the polysilicon structures be the same dimension as the underlying single-crystal silicon structures.

In some embodiments, the asymmetric combdrive device 100 lowers the natural resonant frequency of a device due to the additional contribution on the moment of inertia from its mass distribution (the distance of the fingers 1074 at a radial distance from the rotational axis of spring 1072). However, the combdrive can generate a larger torque than a parallel-plate actuator (such as device 200 without its combdrive portion) under the same applied voltage and the same angular rotation range because its bottom electrode (bulk silicon fingers) are much closer to the top electrode (polysilicon fingers). Therefore, compared to a parallel-plate actuator, the asymmetric combdrive is superior in terms of the operating voltage needed to actuate the same rotational angle under the condition of devices with the same resonant frequency.

A. Asymmetric Combdrive Forces and Torques

The asymmetric combdrive formed by a set of polysilicon movable fingers 1074 and bulk silicon fixed fingers 1012, shown in FIG. 1(a), is actuated by the fringing capacitance that is due to the different thicknesses and heights of the two combs. The majority of the induced fringing electric field lines in this combdrive point downward toward the substrate rather than in an in-plane direction, which is just opposite of what occurs in the conventional in-plane interdigitated combdrive. This type of electrostatic combdrive does not have invariant force output with respect to displacement as in an in-plane interdigitated combdrive, though their geometric shapes from the top view look similar.

The output force and torque due to the changing capacitance, which are expressed in equations (1) and (2), vary with the position of the polysilicon comb fingers:

The force in the into-plane direction is shown in Equation (1).

The torque in the angular motion is shown in Equation (2).

B. Influence of the Combdrive on the Motion of a Membrane

A polysilicon membrane, shown in FIG. 1(a), is suspended by a pair of rectangular bars and is actuated by asymmetric combdrive. There are dimensional criteria associated with the members of this structure; the structure illustrated in FIG. 1(e) is designed with these criteria in mind. The following is a discussion of the influence of the additional symmetric combdrive on the static and dynamic performance of the actuated membrane.

(a) Static Response in Torsional Motion

The rotation angle of the torsional plate is defined by Equation 3 where the applied torque T is expressed in equation (2) and the torsional stiffness of springs (polysilicon rectangular beams), K_{φ} can be described as K_{φ}=2×GIₛₚ/lₛₚ. In this expression, lₛₚ is the length of each beam and G is the elastic shear modulus of polysilicon, which is related to both Young's module E defined as 170 GPa and Poisson's ration v equal to 0.22, according to G=E/2(l+v). The moment of inertia of a spring, Iₛₚ, is expressed Iₛₚ=K_{I}Rₛₚhₛₚ⁴. The parameter Rₛₚ is the ratio of the width of a rectangular spring to its height, Rₛₚ=wₛₚ/hₛₚ. The geometric factor K_{I} is dependent on the spring shape. For a rectangular cross section, K_{I} is given by Equation (4).

According to equation (3), the system has invariant static response even though the combdrive is attached to it.

(b) Dynamic Response in Torsional Mode

For a damping-free system, the dynamic behavior can be described by the following equation of motion.

Iₚθ+K_{φ}θ=T

where the moment of inertia Iₚ of a polysilicon membrane and the attached combs is

Iₚ=ρ×[(lₚ−N_{f}×w_{f})wₚ³hₚ+N_{f}w_{f}(wₚ+2l_{f})³h_{f}]/12

In the expression, the parameters lₚ, wₚ, hₚ denote the length, width and thickness of the polysilicon membrane, the parameters l_{f}, w_{f}, h_{f}, N_{f} denote the length, width, thickness and the number of the polysilicon comb fingers, and ρ is the density of polysilicon, which is 2300 kg/m³. In this process, all polysilicon structures have the same thickness, i.e., hₛₚ=hₚ=h_{f}. The natural resonant frequency, which is geometry dependent, is defined as Equation (5).

Compared to the same structure without the asymmetric combdrive and which is driven by a parallel-plate actuator (i.e., l_{f}=0), the ratio of the natural resonant frequencies is Equation (6).

From the above result, the asymmetric combdrive lowers the natural resonant frequency of a device due to its mass and position. The dimension of the device, shown in FIG. 1(a) and FIG. 1(e), are measured as follows:

hₛₚ=hₚ=h_{f}=1.5 μm (height of polysilicon layer),

lₚ=wₚ=lₛₚ=200 μm, (platform 1071 length and width, and length of spring 1072)

N_{f}=17, (number of fingers)

W_{f}=1.8 μm,

l_{f}=80 μm,

wₛₚ=1.9 μm.

The theoretical natural resonant frequency of the device is f_{R,θ}=4.9 kHz and the ratio f_{R,PP}/f_{R,LC} is equal to 1.32. The natural resonant frequency of this deice was measured to be 4.7 kHz under a small AC signal with a 10V DC bias. The DC bias reduces the effective torsional rigidity, resulting in a lower resonant frequency. This type of device has the potential of achieving a resonant frequency up to tens of kilohertz with several degrees of rotation in either direction.

C. Comparison Between Asymmetric Combdrive and Parallel-Plate Actuator

To compare our combdrive with the most popular torsional actuator, the parallel-plate actuator, a dually-actuated membrane, shown in FIG. 2, was used for the experimental test. The torsional motion actuated by the combdrive can also be accomplished with a parallel-plate actuator consisting of the micromirror and its underlying electrodes. Both experimental and simulation data of the static response to the driving of the parallel-plate actuator and the combdrive with DC bias are shown in FIG. 3. It is found that the fabricated asymmetric combdrive generates a larger rotational angle than the parallel-plate actuator under an equal applied voltage. In our first run, the bottom and top electrodes were separated from each other by a vertical gap of 20 μm, and the gap between the polysilicon and bulk silicon fingers measured 4.2 μm from the top view. Under a 15V DC bias, the measured rotational angles of the membrane when actuated by the combdrive and the parallel-plate actuator were 0.95° and 0.41°, respectively.

To compare the performance of the combdrive and the parallel-plate actuator, the required driving voltage is considered under the conditions of both the same natural resonant frequency and the same rotational angle. By combining equations (2) and (5), the required driving voltage is expressed as follows.

V=2πf_{R,θ}\sqrt{2θ}\sqrt{Iₚ/(2C/2θ)}

V=2πf_{R,θ}(2θ)^{½}(Iₚ/(2C/2θ))^{½}

Thus, according to the experimental data from FIG. 3, the driving voltage required for the parallel-plate actuator is higher than that required for the asymmetric combdrive by 30 percent, while the resonant frequency and the rotational angle of the device are kept the same. The gap between the polysilicon finger and the bulk silicon finger can be potentially reduced to 2 μm, and the required driving voltage can be lowered by additional 50 percent.

The asymmetric combdrive is not only good for actuation but also has some benefits when used as a torsional resonator. Microelectromechanical resonators do not always have the dynamic responses that one would like. As a matter of fact, some device features such as resonant frequency and spring stiffness may fall out of the desired range due to wafer-to-wafer or run-to-run variations in fabrication. Used as a torsional resonator, the asymmetric combdrive has the major advantage of being able to tune the resonant frequency by a dc bias because its differential capacitance varies with respect to the rotational angle. Thus, no additional tuning components or specific frequency-trimming techniques are required. The potential applications of the combdrive include the use as a frequency synchronizer when coupled with a sustaining amplifier, and the use as a mechanical filter when several torsional resonators are linked with each other.

A scanning micromirror with dual actuators, shown in FIG. 2, configured and used as a system with an internal feedback loop will be tested for the control of angular position or angular rate in the future. The internal feedback loop may shorten the response delay so that a faster control response can be achieved. In addition, the device may reduce the size and the cost of a feedback system. To form a feedback loop, the two underlying plates and the membrane could be used as a differential capacitive sensor which enhances the amplitude and linearity of the output signals while the asymmetric combdrive actuates the micromirror in torsional motion.

It is straightforward to fabricate more layers of polysilicon structures on top of the SOI wafer. The present process was one polysilicon layer and one single-crystal silicon layer for the formation of movable structures. With two movable polysilicon layers, the integrated process gains more design flexibility. An example would be the fabrication of folded-out structures directly sitting on single-crystal silicon movable platforms which in conventional surface micromachining might require four-layer polysilicon surface micromachining. Compared to four-layer polysilicon surface micromachining, our integrated technique not only reduces the process topography but also provides a thick single-crystal silicon layer for large force output, high resonant frequency or heavy proof mass. Furthermore, the integrated process could eliminate mechanical coupling between different structures which are linked to each other by a hinge. A hinge can transfer the energy forwards and backwards between translational motion and rotational motion. The coupling increases the system instability if two structures connected by a hinge have overlapped modal frequencies. However, modal frequency separation can be achieved by having the structures fabricated using either polysilicon surface micromachining or DRIE bulk silicon micromachining because the resonant frequency of a structure is mainly inherent to the micromachining process.

In some embodiments a height aspect ratio of 20:1 is used when creating fingers 1011 that will be oxidized. In other embodiments, an aspect ratio of up to about 35:1 is used.

Equations:

F_{z}=N_{f}(V²/2)∂C/∂z (1)

T =N_{f}(V²/2)∂C/∂θ (2)

θ=T/Kφ (3)

K_{I}=5.33×1/16×[1−0.63/Rₛₚ×(1−1/12Rₛₚ⁴)] (4)

$$\begin{matrix}{f}_{R , θ} = \frac{1}{2 π} \sqrt{\frac{{K}_{θ}}{{I}_{p}}} ≅ \frac{1}{2 π} \sqrt{\frac{24 {K}_{I} {GR}_{sp} {h}_{sp}^{3}}{ρ {l}_{sp} [ ( {l}_{p} - {N}_{f} \times {w}_{f} ) {w}_{p}^{3} + {N}_{f} {{w}_{f} ( {w}_{p} + 2 {l}_{f} )}^{3} ]}} & ( 5 ) \\ \frac{{f}_{R , PP}}{{f}_{R , LC}} \sqrt{\frac{{I}_{p , LC}}{{I}_{p , PP}}} = \sqrt{1 + \frac{1 {N}_{f} {w}_{f}}{{I}_{p}} [ 3 ( \frac{{l}_{f}}{{w}_{p}} ) + 6 {( \frac{{l}_{f}}{{w}_{p}} )}^{2} + 4 {( \frac{{l}_{f}}{{w}_{p}} )}^{3} ]} & ( 6 )\end{matrix}$$

It is understood that the above description is intended to be illustrative, and not restrictive. Many other embodiments will be apparent to those of skill in the art upon reviewing the above description. The scope of the invention should, therefore, be determined with reference to the appended claims, along with the full scope of equivalents to which such claims are entitled.

What is claimed is:

1. A method for making a microelectromechanical system, the method comprising:
(a) providing a starting substrate that has a silicon layer;
(b) etching a plurality of trenches to leave a plurality of vertical-walled silicon structures standing on the substrate;
(c) thermally and substantially completely oxidizing the vertical-walled silicon structures;
(d) substantially filling spaces between the oxidized vertical-walled silicon structures with an oxide of silicon to form an oxide block; and
(e) planarizing a surface of the oxide block.

2. The method of claim 1, further comprising:
(f) depositing a polysilicon layer on the oxide block;
(g) patterning the polysilicon layer; and
(f) removing the oxide block under the patterned polysilicon layer.

3. The method of claim 2, wherein the (g) patterning the polysilicon layer includes forming an asymmetrical comb drive.

4. A method for making a directional microphone having a proof mass and a membrane, the method comprising:
(a) providing an SOI (silicon-on-insulator) starting wafer that has a single-crystal silicon substrate and that has a surface silicon layer of the thickness for the proof mass;
(b) forming an oxide block on the top surface, including:
(i) deep etching to form beam structures;
(ii) performing a thermal oxidation;
(iii) oxide refilling using low pressure chemical vapor deposition (LPCVD), and
(iv) chemical-mechanical polishing (CMP);
(c) forming a thin-film membrane, including:
(i) etching the single-crystal silicon reserved for formation of corrugation,
(ii) window etching for the thin-film membrane anchored onto the top silicon layer, and
(iii) depositing a thin-film deposition; and
(d) backside-etch releasing, including:
(i) single-crystal all-through etching from the backside of the wafer, and
(ii) hydrofluoric acid (HF) releasing.

5. The method of claim 4, wherein the thin-film membrane is polysilicon.

6. The method of claim 4, wherein the thermal oxidation enlarges a dimension of layout.

7. The method of claim 4, wherein a thin oxide on top of the top silicon layer functions as the mask for step (c)(i)

8: A system for making a microelectromechanical system on a starting substrate that has a silicon layer, the method comprising:
means for etching a plurality of trenches to leave a plurality of vertical-walled silicon structures standing on the substrate;
means for thermally and substantially completely oxidizing the vertical-walled silicon structures; and
means for substantially filling spaces between the oxidized vertical-walled silicon structures with an oxide of silicon to form an oxide block.
